(19) United States
(12) Patent Application Publication
(10) Pub. No.: US 2010/0050944 A1
(43) Pub. Date: Mar. 4, 2010

(54) FILM DEPOSITION APPARATUS, SUBSTRATE PROCESS APPARATUS, AND TURNTABLE

(75) Inventors: HITOSHI KATO, Oshu-Shi (JP); MANABU HONMA, Oshu-Shi (JP); TOMOKI HANEISHI, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/550,967

(22) Filed: Aug. 31, 2009

(30) Foreign Application Priority Data
Sep. 4, 2008 (JP) 2008-227029
Aug. 4, 2009 (JP) 2009-181806

(51) Int. Cl. C23C 16/458; C23C 16/00

(52) U.S. Cl. 118/730

(57) ABSTRACT

A film deposition apparatus for depositing a film on a substrate by carrying out a cycle of alternately supplying at least two kinds of reaction gases that react with each other to the substrate to produce a layer of a reaction product in a chamber is disclosed. This film deposition apparatus includes a turntable rotatably provided in the chamber, a substrate receiving portion that is provided in the turntable and the substrate is placed in, a first reaction gas supplying portion, a second reaction gas supplying portion, a separation gas supplying portion, an upper holding member that may be pressed on an upper center portion of the turntable and is made of one of quartz and a ceramic material; and a lower holding member that may be pressed on a lower center portion of the turntable in order to rotatably hold the turntable in cooperation with the upper holding member.

### CROSS-REFERENCE TO RELATED APPLICATIONS

The present application is based on Japanese Patent Applications No. 2008-227029 and No. 2009-181806, filed with the Japanese Patent Office on Sep. 4, 2008, and Aug. 4, 2009, respectively, the entire contents of which are hereby incorporated herein by reference.

### BACKGROUND OF THE INVENTION

1. Field of the Invention

The present invention relates to a film deposition apparatus for depositing a film on a substrate by carrying out plural cycles of supplying in turn at least two source gases to the substrate in order to form plural layers of a reaction product, a substrate process apparatus including the film deposition apparatus, and a turntable to be used in the film deposition apparatus.

2. Description of the Related Art

As a film deposition technique in a semiconductor fabrication process, there has been known a process, in which a first reaction gas is adsorbed on a surface of a semiconductor wafer (referred to as a wafer hereinafter) and the like under vacuum and then a second reaction gas is adsorbed on the surface of the wafer in order to form one or more atomic or molecular layers through reaction of the first and the second reaction gases on the surface of the wafer, and such an alternating adsorption of the gases is repeated plural times, thereby depositing a film on the wafer. This technique is called Atomic Layer Deposition (ALD) or Molecular Layer Deposition (MLD) and advantageous in that the film thickness can be controlled at higher accuracy by the number of times of alternately supplying the reaction gases, and in that the deposited film can have excellent uniformity over the wafer. Therefore, this deposition method is thought to be promising as a film deposition technique that can address further miniaturization of semiconductor devices.

Such a film deposition method may be preferably used, for example, for depositing a dielectric material to be used as a gate insulator. When silicon dioxide (SiO₂) is deposited as the gate insulator, a bis (tertiary-butylamino) silane (BTBAS) gas or the like is used as a first reaction gas (source gas) and ozone gas or the like is used as a second gas (oxidation gas).

In order to carry out such a deposition method, use of a single-wafer deposition apparatus having a vacuum chamber and a shower head at a top center portion of the vacuum chamber and a deposition method using such an apparatus has been under consideration. In the deposition apparatus, the reaction gases are introduced into the chamber from the top center portion, and unreacted gases and by-products are evacuated from a bottom portion of the chamber. When such a deposition chamber is used, it takes a long time for a purge gas to purge the reaction gases, resulting in an extremely long process time because the number of cycles may reach several hundred. Therefore, a deposition method and apparatus that enable high throughput is desired.

Under these circumstances, film deposition apparatuses having a vacuum chamber and a turntable that holds plural wafers along a rotation direction have been proposed in order to carry out ALD or MLD, in documents listed below.

Patent Document 1 listed below discloses a deposition apparatus whose process chamber has a shape of a flattened cylinder. The process chamber is divided into two half circle areas. Each area has an evacuation port provided to surround the area at the top portion of the corresponding area. In addition, the process chamber has a gas inlet port that introduces separation gas between the two areas along a diameter of the process chamber. With these configurations, while different reaction gases are supplied into the corresponding areas and evacuated from above by the corresponding evacuation ports, a turntable is rotated so that the wafers placed on the turntable can alternately pass through the two areas.

Patent Document 2 discloses a process chamber in which four wafers are placed on a wafer support member (rotation table) at equal angular intervals along a rotation direction of the wafer support member, first and second gas ejection nozzles are located along the rotation direction and oppose the wafer support member, and purge nozzles are located between the first and the second gas ejection nozzles. In this process chamber, the wafer support member is horizontally rotated in order to deposit a film on the wafers.

Patent Document 3 discloses a process chamber that is divided into plural process areas along the circumferential direction by plural partitions. Below the partitions, a circular rotatable susceptor on which plural wafers are placed is provided leaving a slight gap in relation to the partitions.

Moreover, Patent Document 4 discloses a technique in which a circular gas supplying plate is divided into eight sector areas, four gas inlet ports for AsH₃ gas, H₂ gas, trimethyl gallium (TMG) gas, and H₂ gas, respectively, are arranged at angular intervals of 90 degrees, evacuation ports are located between the adjacent gas inlet ports, and a susceptor that holds plural wafers and opposes the gas supplying plate is rotated.

Patent Document 5 discloses a process chamber in which an area above a turntable is partitioned in a crisscross manner by four vertical walls; four wafers are arranged below the corresponding partitioned areas; and an injector unit having a source gas injector, a cross-shaped reaction gas injector, and a purge gas injector that are arranged in turn along a rotation direction. In this process chamber, the injector unit horizontally rotates around a center axis thereof above the four wafers while ejecting a source gas, a purge gas, a reaction gas, and another purge gas, and these gases are evacuated from a peripheral area of the turntable.

Furthermore, Patent Document 6 (Patent Documents 7, 8) discloses a film deposition apparatus preferably used for an Atomic Layer CVD method that causes plural gases to be alternately adsorbed on a target (a wafer). In the apparatus, a susceptor that holds the wafer is rotated, while source gases and purge gases are supplied to the susceptor from above. Paragraphs 0023, 0024, and 0025 of the document describe partition walls that extend in a radial direction from a center of a chamber, and gas ejection holes that are formed in a bottom of the partition walls in order to supply the source gases or the purge gas to the susceptor, so that an inert gas as the purge gas ejected from the gas ejection holes produces a gas curtain. Regarding evacuation of the gases, paragraph 0058 of the document describes that the source gases are evacuated through an evacuation channel 30a, and the purge gases are evacuated through an evacuation channel 30b.

Patent Document 1: United States Patent Publication No. 7,153,542 (FIGS. 6A, 6B)

Patent Document 2: Japanese Patent Application Laid-Open Publication No. 2001-254181 (FIGS. 1, 2)

Patent Document 3: Japanese Patent Publication No. 3,144,664 (FIGS. 1, 2, claim 1)

Patent Document 4: Japanese Patent Application Laid-Open Publication No. H4-287912

Patent Document 5: United States Patent Publication No. 6,634,314

Patent Document 6: Japanese Patent Application Laid-Open Publication No. 2007-247066 (paragraphs 0023 through 0025, 0058, FIGS. 12 and 18)

Patent Document 7: United States Patent Publication No. 2007/218701

Patent Document 8: United States Patent Publication No. 2007/218702

However, in the apparatus described in Patent Document 1, because the evacuation port is provided at the upper portion of the process chamber and between the separation gas inlet port and the area where reaction gas is supplied, and the reaction gas is evacuated along with the separation gas upward from the evacuation port, particles in the process chamber may be blown up by the upward flow of the gases and fall on the wafers, leading to contamination of the wafers.

In addition, in the process chamber described in Patent Document 2, the gas curtain cannot completely prevent mixture of the reaction gases but may allow one of the reaction gases to flow through the gas curtain to be mixed with the other reaction gas partly because the gases flow along the rotation direction due to the rotation of the wafer support member. Moreover, the first (second) reaction gas discharged from the first (second) gas outlet nozzle may flow through the center portion of the wafer support member to meet the second (first) gas, because centrifugal force is not strongly applied to the gases in a vicinity of the center of the rotating wafer support member. Once the reaction gases are mixed in the chamber, an MLD (or ALD) mode film deposition cannot be carried out as expected.

In the apparatus described in Patent Document 3, the process gas introduced into one of the process areas may spread into the adjacent process area through the gap below the partition, and be mixed with another process gas introduced into the adjacent process area. Moreover, the process gases may be mixed in the evacuation chamber, so that the wafer is exposed to the two process gases at the same time. Therefore, ALD (or MLD) mode deposition cannot be carried out in a proper manner by this process chamber.

Patent Document 4 does not provide any realistic measures to prevent two source gases (AsH₃, TMG) from being mixed. Because of the lack of such measures, the two source gases may be mixed around the center of the susceptor and through the H₂ gas supplying plates. Moreover, because the evacuation ports are located between the adjacent two gas supplying plates to evacuate the gases upward, particles are blown up from the susceptor surface, which leads to wafer contamination.

In the process chamber described in Patent Document 5, after one of the injector pipes passes over one of the quarters, this quarter cannot be purged by the purge gas in a short period of time. In addition, the reaction gas in one of the partitioned areas can easily flow into an adjacent one of the partitioned areas and the reaction gases react with each other over the wafers.

The present invention has been made in view of the above, and provides a film deposition apparatus, a substrate process apparatus and a turntable to be used in the film deposition apparatus which are capable of reducing contamination due to metal powders or the like caused from the turntable and its vicinity and cracks/breakage, when at least two source gases are supplied in turn to a substrate to form plural layers of a reaction product and thus deposit a film on the substrate.

### SUMMARY OF THE INVENTION

A first aspect of the present invention provides a film deposition apparatus for depositing a film on a substrate by carrying out a cycle of alternately supplying at least two kinds of reaction gases that react with each other to the substrate to produce a layer of a reaction product in a chamber. The film deposition apparatus includes a turntable rotatably provided in the chamber; a substrate receiving portion that is provided in the turntable and the substrate is placed in; a first reaction gas supplying portion configured to supply a first reaction gas to a surface having the substrate receiving portion; a second reaction gas supplying portion configured to supply a second reaction gas to the surface having the substrate receiving portion, the second reaction gas supplying portion being separated from the first reaction gas supplying portion along a rotation direction of the turntable; a separation area located along the rotation direction between a first process area in which the first reaction gas is supplied and a second process area in which the second reaction gas is supplied, wherein the separation area includes a separation gas supplying portion that supplies a first separation gas, and a ceiling surface that creates in relation to the turntable a thin space in which the first separation gas may flow from the separation area to the process area side in relation to the rotation direction; a center area that is located substantially in a center portion of the chamber in order to separate the first process area and the second process area, and has an ejection hole that ejects a second separation gas along the surface having the substrate receiving area; an evacuation opening provided in the chamber in order to evacuate the chamber; an upper holding member that may be pressed on an upper center portion of the turntable and is made of one of quartz and a ceramic material; and a lower holding member that may be pressed on a lower center portion of the turntable in order to rotatably hold the turntable in cooperation with the upper holding member.

A second aspect of the present invention provides a film deposition apparatus for depositing a film on a substrate by carrying out a cycle of alternately supplying at least two kinds of reaction gases that react with each other to the substrate to produce a layer of a reaction product in a chamber. The film deposition apparatus includes a turntable rotatably provided in the chamber; a substrate receiving portion that is provided in the turntable and the substrate is placed in; a first reaction gas supplying portion configured to supply a first reaction gas to a surface having the substrate receiving portion; a second reaction gas supplying portion configured to supply a second reaction gas to the surface having the substrate receiving portion, the second reaction gas supplying portion being separated from the first reaction gas supplying portion along a rotation direction of the turntable; separation area located along the rotation direction between a first process area in which the first reaction gas is supplied and a second process area in which the second reaction gas is supplied, wherein the separation area includes a separation gas supplying portion that supplies a first separation gas, and a ceiling surface that creates in relation to the turntable a thin space in which the first separation gas may flow from the separation area to the process area side in relation to the rotation direction; a center area that is located substantially in a center portion of the chamber in order to separate the first process area and the second process area, and has an ejection hole that ejects a second separation gas along the surface having the substrate receiving area; an evacuation opening provided in the chamber in order to evacuate the chamber; an upper holding member that may be pressed on an upper center portion of the turntable; and a lower holding member that may be pressed on a lower center portion of the turntable in order to rotatably hold the turntable in cooperation with the upper holding member, wherein an area where the upper holding member and the turntable contact each other is made of a ceramic material, and an area where the lower holding member and the turntable contact each other is made of a ceramic material.

A third aspect of the present invention provides a turntable rotatably provided in a film deposition apparatus and held in such a manner that an upper holding member is pressed on an upper center portion of the turntable and a lower holding member is pressed on a lower center portion of the turntable. The turntable includes a ceramic film formed on areas of the turntable, the areas contacting the upper holding member and the lower holding member, respectively.

### BRIEF DESCRIPTION OF THE DRAWINGS

FIG. 1 is a cross-sectional view of a film deposition apparatus according to an embodiment of the present invention;

FIG. 2 is a perspective view illustrating an inner configuration of the film deposition apparatus;

FIG. 3 is a plan view of the film deposition apparatus;

FIGS. 4A and 4B show process areas and a separation area in the film deposition apparatus;

FIG. 5 is a partial cross-sectional view illustrating the film deposition apparatus;

FIG. 6 is a partial broken perspective view illustrating the film deposition apparatus;

FIG. 7 is an explanatory view illustrating a flow pattern of a separation gas and a purge gas;

FIG. 8 is a partial broken perspective view illustrating the film deposition apparatus;

FIG. 9 is a cross-sectional view illustrating a turntable held with holding members;

FIG. 10 is an enlarged partial cross-sectional view of the turntable held with the holding members;

FIG. 11 is another cross-sectional view illustrating the turntable held with other holding members;

FIG. 12 is another cross-sectional view illustrating the turntable held with other holding members;

FIG. 13 is an explanatory view illustrating that a first reaction gas and a second reaction gas are separated by separation gases;

FIG. 14A is a partial plan view for explaining an example of a size of a convex portion used in a separation area;

FIG. 14B is a partial cross-sectional view for an example of a size of the convex portion used in a separation area;

FIG. 15 is a cross-sectional view of another separation area;

FIG. 16 is a cross-sectional view illustrating another example of the convex portion used in the separation area;

FIG. 17 is a bottom view illustrating another example of a gas ejection hole of a reaction gas supplying portion;

FIG. 18 is a cross-sectional view illustrating a film deposition apparatus according to another embodiment;

FIG. 19 is a cross-sectional view illustrating a film deposition apparatus according to another embodiment;

FIG. 20 is a perspective view of an inner configuration of a film deposition apparatus according to another embodiment;

FIG. 21 is a cross-sectional view illustrating a film deposition apparatus according to another embodiment;

FIG. 22 is a cross-sectional view illustrating a film deposition apparatus according to another embodiment; and

FIG. 23 is a schematic plan view of an example of a substrate process system including a film deposition apparatus according to an embodiment of the present invention.

### DETAILED DESCRIPTION OF THE PREFERRED EMBODIMENT

According to an embodiment of the present invention, when at least two source gases are supplied in turn to a substrate to form plural layers of a reaction product, and thus deposit a film on the substrate, contamination due to metal powders or the like caused from a turntable and its vicinity can be reduced, and breakage/cracks of the turntable can be avoided. Therefore, film deposition can be carried out in a clean environment for a long time, thereby reducing defective devices and enhancing an apparatus utilization efficiency.

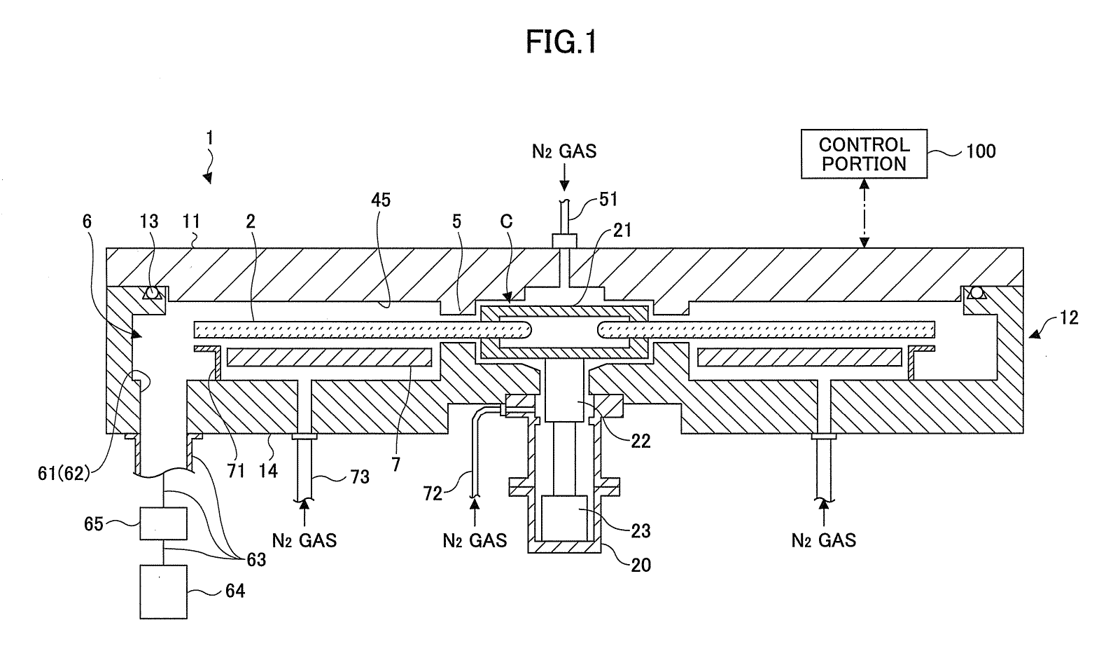

Referring to the accompanying drawings, a film deposition apparatus according to an embodiment of the present invention will be explained. As shown in FIG. 1, a film deposition apparatus according to the embodiment of the present invention has a vacuum chamber 1 having a flattened cylinder shape, and a turntable 2 that is located inside the vacuum chamber 1 and has a rotation center at a center of the vacuum chamber 1. The vacuum chamber 1 is configured so that a ceiling plate 11 can be separated from a chamber body 12. The ceiling plate 11 is pressed onto the chamber body 12 via a ceiling member such as an O ring 13, so that the vacuum chamber 1 is hermetically sealed. On the other hand, the ceiling plate 11 can be raised by a driving mechanism (not shown) when the ceiling plate 11 has to be removed from the chamber body 12.

The turntable 2 is fixed onto a cylindrically shaped core portion 21. The core portion 21 is fixed on a top end of a rotational shaft 22 that extends in a vertical direction. The rotational shaft 22 penetrates a bottom portion 14 of the chamber body 12 and is fixed at the lower end to a driving mechanism 23 that can rotate the rotational shaft 22 clockwise, in this embodiment. The rotational shaft 22 and the driving mechanism 23 are housed in a case body 20 having a cylinder with a bottom. The case body 20 is hermetically fixed to a bottom surface of the bottom portion 14 via a flanged portion, which isolates an inner environment of the case body 20 from an outer environment.

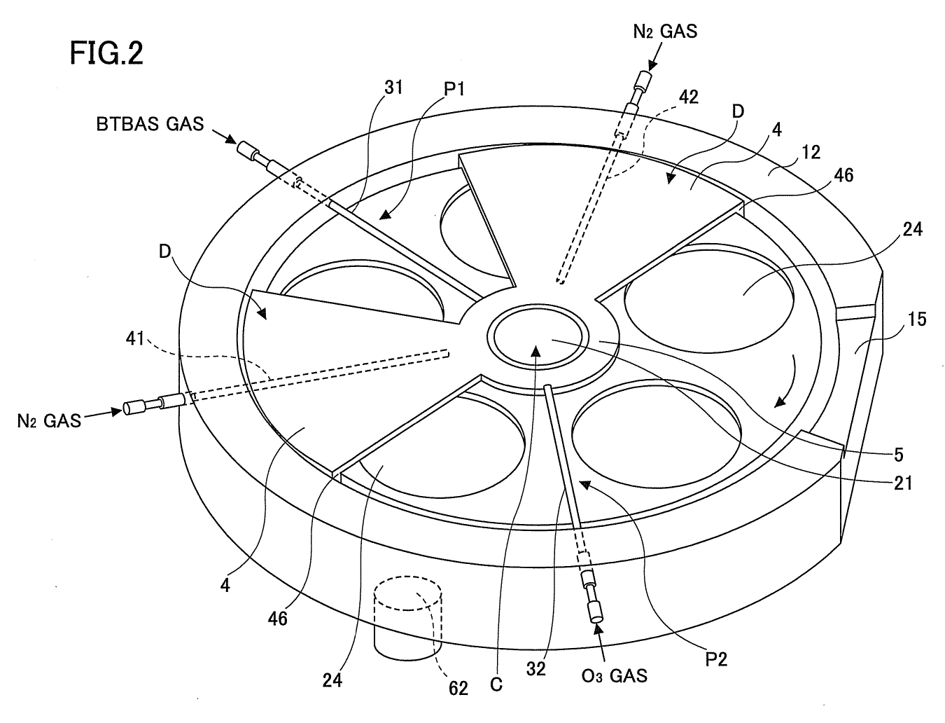

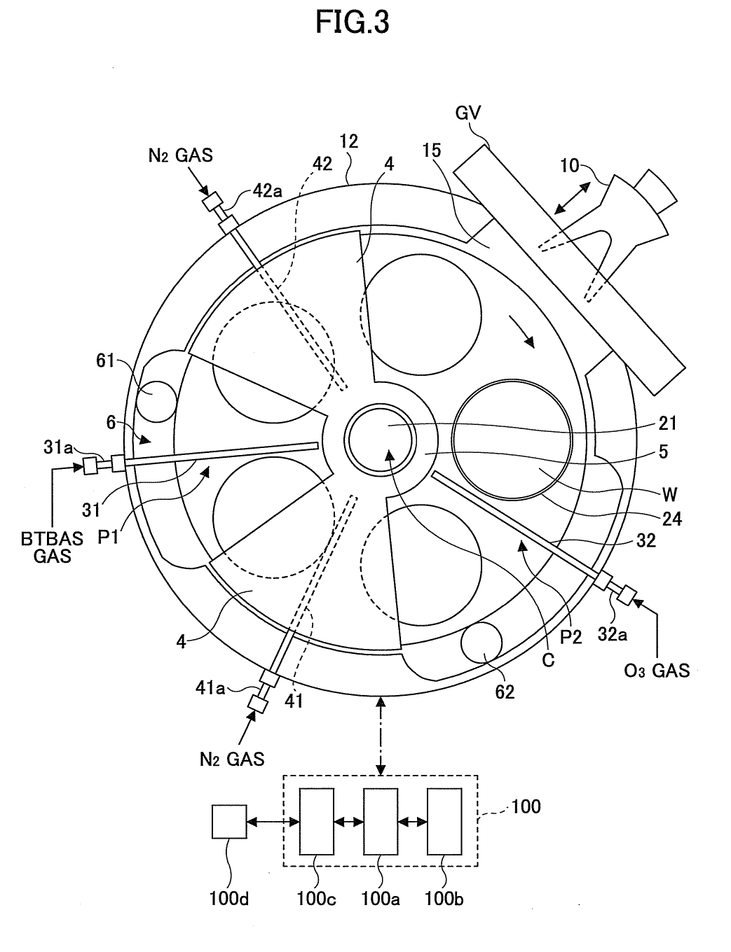

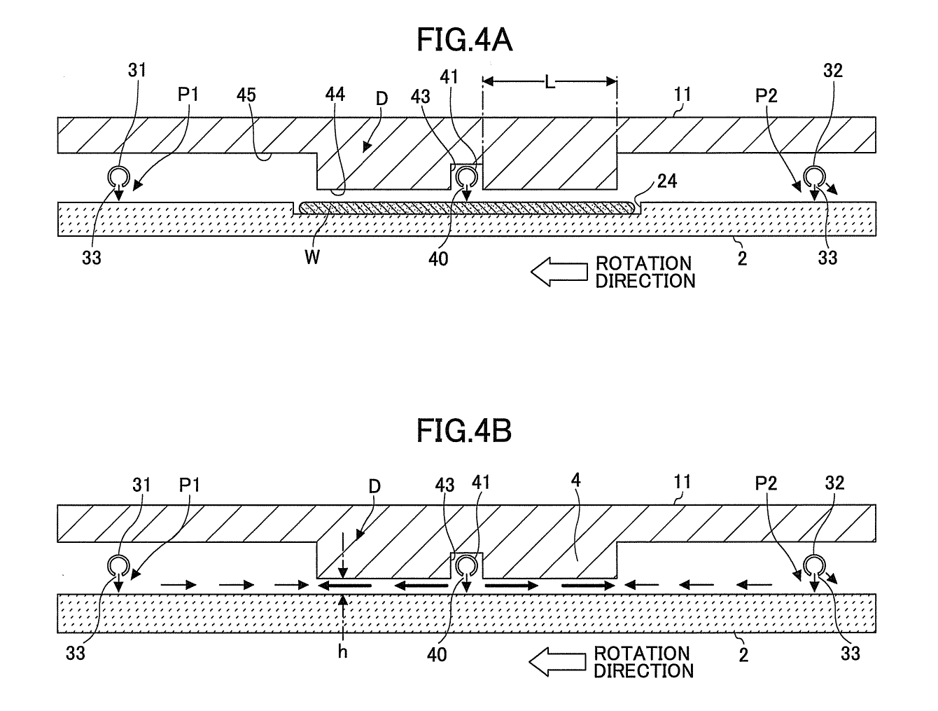

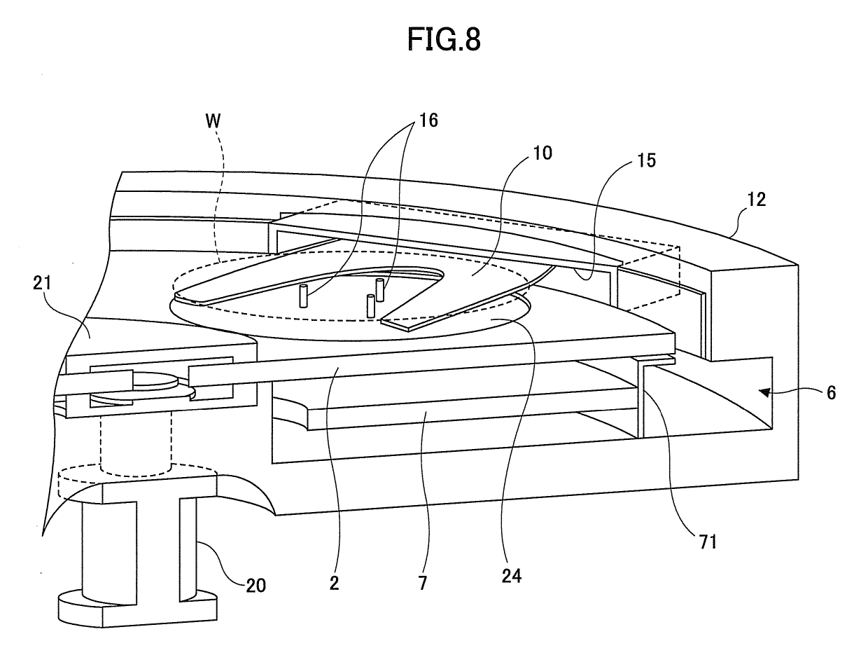

As shown in FIGS. 2 and 3, plural (e.g., five) circular concave portions 24, each of which receives a wafer W, are formed in a top surface of the turntable 2, although only one wafer W is illustrated in FIG. 3. FIG. 4A is a projected cross-sectional diagram taken along a concentric circle. As shown in FIG. 4A, the concave portion 24 has a diameter slightly larger, for example, by 4 mm than the diameter of the wafer W and a depth equal to a thickness of the wafer W. Therefore, when the wafer W is placed in the concave portion 24, a surface of the wafer W is at the same elevation of a surface of an area of the turntable 2, the area excluding the concave portions 24. If there is a relatively large step between the area and the wafer W, pressure changes are caused by the step. Therefore, from a viewpoint of a thickness uniformity across the wafer W, it is preferable to configure the two surfaces with the same elevation. While “the same elevation” may mean here that a height difference is less than or equal to about 5 mm, the difference has to be as close to zero as possible to the extent allowed by machining accuracy. In the bottom of the concave portion 24 there are formed three through holes (not shown) through which three corresponding elevation pins (see FIG. 8) are raised/lowered. The elevation pins support a back surface of the wafer W and raises/lowers the wafer W.

The concave portions 24 are wafer receiving areas provided to position the wafers W and prevent the wafers W from being thrown out by centrifugal force caused by rotation of the turntable 2. However, the wafer W receiving areas are not limited to the concave portions 24, but may be configured by plural guide members that are located along a circumferential direction of the turntable 2 on the turntable 2. For example, the wafer receiving areas may be configured by electrostatic chucks. In this case, an area where the wafer W is held by the electrostatic chucks is the wafer receiving area.

Referring to FIGS. 2 and 3, the vacuum chamber 1 includes a first reaction gas nozzle 31, a second reaction gas nozzle 32, and separation gas nozzles 41, 42 above the turntable 2, all of which extend in radial directions and at predetermined angular intervals. With this configuration, the concave portions 24 can move through and below the nozzles 31, 32, 41, and 42. In the illustrated example, the second reaction gas nozzle 32, the separation gas nozzle 41, the first reaction gas nozzle 31, and the separation gas nozzle 42 are arranged clockwise in this order, viewed from above. These gas nozzles 31, 32, 41, and 42 penetrate the circumferential wall portion of the chamber body 12 and are supported by attaching their base ends, which are gas inlet ports 31a, 32a, 41a, 42a, respectively, in the outer circumference of the wall portion. Although the gas nozzles 31, 32, 41, 42 are introduced into the vacuum chamber 1 from the circumferential wall portion of the vacuum chamber 1 in the illustrated example, these nozzles 31, 32, 41, 42 may be introduced from a ring-shaped protrusion portion 5 (described later). In this case, an L-shaped conduit may be provided in order to be open on the outer circumferential surface of the protrusion portion 5 and on the outer top surface of the ceiling plate 11. With such an L-shaped conduit, the nozzle 31 (32, 41, 42) can be connected to one opening of the L-shaped conduit inside the vacuum chamber 1 and the gas inlet port 31a (32a, 41a, 42a) can be connected to the other opening of the L-shaped conduit outside the vacuum chamber 1.

Although not shown, the reaction gas nozzle 31 is connected to a gas supplying source of bis (tertiary-butylamino) silane (BTBAS), which is a first source gas, and the reaction gas nozzle 32 is connected to a gas supplying source of O₃ (ozone) gas, which is a second source gas. In addition, the separation gas nozzles 41, 42 are connected to gas supplying sources of N₂ (nitrogen) gas (not shown).

The reaction gas nozzles 31, 32 have plural ejection holes 33 to eject the corresponding source gases downward. The plural ejection holes 33 are arranged in longitudinal directions of the reaction gas nozzles 31, 32 at predetermined intervals. The reaction gas nozzles 31, 32 are a first reaction gas supplying portion and a second reaction gas supplying portion, respectively, in this embodiment. In addition, an area below the reaction gas nozzle 31 is a first process area P1 in which the BTBAS gas is adsorbed on the wafer W, and an area below the reaction gas nozzle 32 is a second process area P2 in which the O₃ gas is adsorbed on the wafer W.

The separation gas nozzles 41, 42 are provided to create corresponding separation areas D that separate the first process area P1 and the second process area P2. In each of the separation areas D, there is provided a convex portion 4 on the ceiling plate 11, as shown in FIGS. 2 through 4. The convex portion 4 has a top view shape of a sector whose apex lies at the center of the vacuum chamber 1 and whose arced periphery lies near and along the inner circumferential wall of the chamber body 12. In addition, the convex portion 4 has a groove portion 43 that extends in the radial direction so that the groove portion 43 substantially bisects the convex portion 4. The separation gas nozzle 41 (42) is located in the groove portion 43. Distances from a center axis of the separation gas nozzle 41 (42) to sides of the convex portion 4 in both directions are equal.

With the above configuration, there are flat low ceiling surfaces 44 (first ceiling surfaces) on both sides of the separation gas nozzle 41 (42), and high ceiling surfaces 45 (second ceiling surfaces) outside of the corresponding low ceiling surfaces 44, as shown in FIG. 4A. The convex portion 4 (ceiling surface 44) provides a separation space, which is a thin space, between the convex portion 4 and the turntable 2 in order to impede the first and the second gases from entering the thin space and from being mixed.

Taking an example of the separation gas nozzle 41, this nozzle 41 may impede the O₃ gas and the BTBAS gas from entering between the convex portion 4 and the turntable 2 from the upstream side and the downstream side of the rotation direction, respectively. “The gases being impeded from entering” means that the N₂ gas as the separation gas ejected from the separation gas nozzle 41 diffuses between the first ceiling surfaces 44 and the upper surface of the turntable 2 and flows out to a space below the second ceiling surfaces 45, which are adjacent to the corresponding first ceiling surfaces 44 in the illustrated example, so that the gases cannot enter the separation space from the space below the second ceiling surfaces 45. “The gases cannot enter the separation space” means not only that the gases are completely prevented from entering the separation space, but that the gases cannot proceed farther toward the separation gas nozzle 41 and thus be mixed with each other even if a fraction of the reaction gases enter the separation space. Namely, as long as such an effect is provided, the separation area D separates the first process area P1 and the second process area P2. Incidentally, the BTBAS gas or the O₃ gas adsorbed on the wafer W can pass through below the convex portion 4. Therefore, the gases in “the gases being impeded from entering” mean the gases in a gaseous phase.

Referring to FIGS. 1, 2, and 3, a ring-shaped protrusion portion 5 is provided on a back surface of the ceiling plate 11 so that the inner circumference of the protrusion portion 5 faces the outer circumference of the core portion 21. The protrusion portion 5 opposes the turntable 2 at an outer area of the core portion 21. In addition, the protrusion portion 5 and the convex portion 4 are integrally formed and thus a back surface of the protrusion portion 5 and a back surface of the convex portion 4 form one plane surface. In other words, a height of the back surface of the protrusion portion 5 from the turntable 2 is the same as a height of the back surface (first ceiling 44) of the convex portion 4, which will be referred to as a height h below. Incidentally, the convex portion 4 is formed not integrally with but separately from the protrusion portion 5 in other embodiments. FIGS. 2 and 3 show the inner configuration of the vacuum chamber 1 whose top plate 11 is removed while the convex portions 4 remain inside the vacuum chamber 1.

The separation area D is configured by forming the groove portion 43 in a sector-shaped plate to be the convex portion 4, and locating the separation gas nozzle 41 (42) in the groove portion 43 in the above embodiment. However, two sector-shaped plates may be attached on the lower surface of the ceiling plate 11 by screws so that the two sector-shaped plates are located on both sides of the separation gas nozzle 41 (32).

The separation gas nozzles 41, 42 have plural ejection holes 40 open downward. The plural ejection holes 40 have an inner diameter of about 0.5 mm and are arranged at predetermined intervals of about 10 mm in longitudinal directions of the separation gas nozzles 41, 42. In the reaction gas nozzles 31, 32, the ejection holes 33 open downward have diameters of about 0.5 mm and are arranged at intervals of about 10 mm along longitudinal directions of the reaction gas nozzles 31, 32.

When the wafer W having a diameter of about 300 mm is supposed to be processed in the vacuum chamber 1, the convex portion 4 has a circumferential length of, for example, about 146 mm along an inner arc that is at a distance of 140 mm from the rotation center of the turntable 2, and a circumferential length of, for example, about 502 mm along an outer arc corresponding to the outermost portion of the concave portions 24 of the turntable 2 in this embodiment. In addition, a circumferential length from one side wall of the convex portion 4 through the nearest side wall of the groove portion 43 along the outer arc is about 246 mm.

In addition, the height h (FIG. 4A) of the back surface of the convex portion 4, or the ceiling surface 44, measured from the top surface of the turntable 2 (or the wafer W) is, for example, about 0.5 mm through about 10 mm, and preferably about 4 mm. In this case, the rotational speed of the turntable 2 is, for example, 1 through 500 revolutions per minute (rpm). In order to ascertain the separation function performed by the separation area D, the size of the convex portion 4 and the height h of the ceiling surface 44 from the turntable 2 may be determined depending on the pressure in the vacuum chamber 1 and the rotational speed of the turntable 2 through experimentation. Incidentally, the separation gas is N₂ in this embodiment but may be an inert gas such as He and Ar, or H₂ or other gases in other embodiments, as long as the separation gas does not affect the deposition of silicon dioxide.

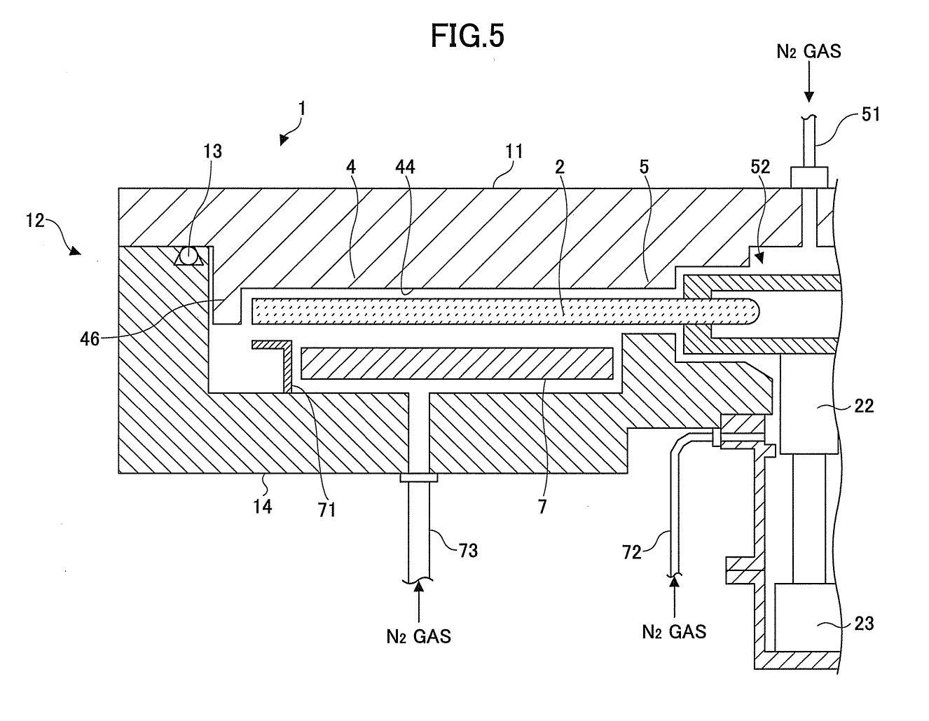

As described above, the vacuum chamber 1 is provided with the first ceiling surfaces 44 and the second ceiling surfaces 45 higher than the first ceiling surfaces 44, which are alternately arranged in the circumferential direction. FIG. 1 shows a cross section of a portion where the higher ceiling surface is formed; and FIG. 5 shows a cross section of a portion of the vacuum chamber 1 where the lower ceiling surface 44 is formed. Referring to FIGS. 2 and 5, the convex portion 4 has a bent portion 46 that bends in an L-shape at the outer circumferential edge of the convex portion 4. Although there are slight gaps between the bent portion 46 and the turntable 2 and between the bent portion 46 and the chamber body 12 because the convex portion 4 is attached on the back surface of the ceiling portion 11 and removed from the chamber body 12 along with the ceiling portion 11, the bent portion 46 substantially fills in a space between the turntable 2 and the chamber body 12, thereby preventing the first reaction gas (BTBAS) ejected from the first reaction gas nozzle 31 and the second reaction gas (ozone) ejected from the second reaction gas nozzle 32 from being mixed through the space between the turntable 2 and the chamber body 12. The gaps between the bent portion 46 and the turntable 2 and between the bent portion 46 and the chamber body 12 may be the same as the height h of the ceiling surface 44 from the turntable 2. In the illustrated example, a side wall facing the outer circumferential surface of the turntable 2 serves as an inner circumferential wall of the vacuum chamber 1.

The inner circumferential wall of the chamber body 12 is close to the outer circumferential surface of the bent portion 46 and stands upright in the separation area D, as shown in FIG. 5, and is dented outward from a height corresponding to the outer circumferential surface of the turntable 2 down through the bottom portion 14 of the chamber body 12 in areas other than the separation area D, as shown in FIG. 1. The dented area is referred to as an evacuation area 6 below. As shown in FIGS. 1 and 3, two evacuation ports 61, 62 are provided in the corresponding evacuation areas 6. The evacuation ports 61, 62 are connected to a commonly-provided evacuation unit 64 including, for example, a vacuum pump via corresponding evacuation pipes 63. Incidentally, reference numeral “65” in FIG. 1 is a pressure control unit that may be commonly-provided for the evacuation ports 61, 62, In order to ensure the separation effect by the separation area D, the evacuation ports 61, 62 are located one on each side of each of separation areas D, so that the evacuation ports 61, 62 substantially exclusively evacuate the corresponding reaction gases (BTBAS, O3). In the illustrated example, the evacuation port 61 is located between the first reaction gas nozzle 31 and the convex portion 4 that is located downstream relative to the clockwise rotation direction of the turntable 2 with respect to the first reaction gas nozzle 31; the evacuation port 62 is located between the first reaction gas nozzle 32 and the convex portion 4 that is located downstream relative to the clockwise rotation direction of the turntable 2 with respect to the first reaction gas nozzle 32, when viewed from above. The number of the evacuation ports is not limited to two, but three or four or more evacuation ports may be provided. While the evacuation ports 61, 62 are located below the turntable 2 to evacuate the vacuum chamber 1 through an area between the inner circumferential wall of the chamber body 12 and the outer circumferential surface of the turntable 2 in the illustrated example, the evacuation ports may be located in the side wall of the chamber body 12. In addition, when the evacuation ports 61, 62 are provided in the side wall of the chamber body 12, the evacuation ports 61, 62 may be located higher than the turntable 2. In this case, the gases flow along the upper surface of the turntable 2 into the evacuation ports 61, 62 located higher than the turntable 2. Therefore, it is advantageous in that particles in the vacuum chamber 1 are not blown upward by the gases, compared to when the evacuation ports are provided, for example, in the ceiling plate 11.

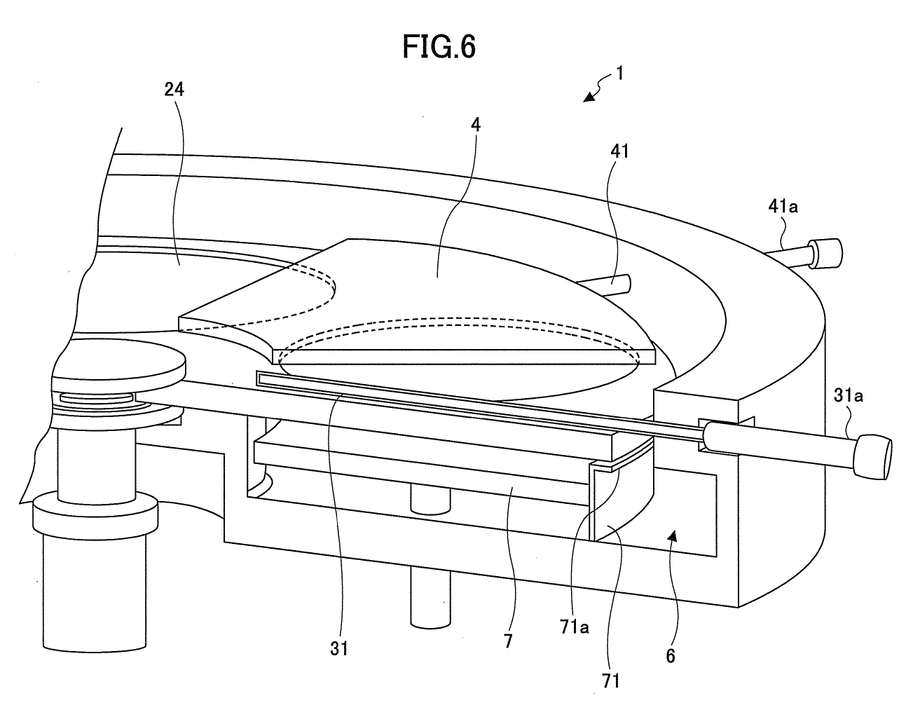

Referring to FIGS. 1, 5, and 6, a heater unit 7 is provided between the turntable 2 and the bottom portion 14 of the vacuum chamber 1 in order to heat the turntable 2 and thus the wafer W on the turntable 2, up to a temperature set by a process recipe. Below the circumferential portion of the turntable 2, a cover member 71 is provided surrounding the heater unit 7 in order to separate an atmosphere in a heater unit housing space where the heater unit 7 is housed and an atmosphere outside of the heater unit housing space. The cover member 71 has a flange portion 71a at the top. The flange portion 71a is arranged so that a slight gap is maintained between the back surface of the turntable 2 and the flange portion in order to prevent gas from flowing inside the cover member 71.

Referring to FIGS. 1, 5 and 7, part of the bottom portion 14, the part being closer to the rotation center of the turntable 2 than the space where the heater unit 7 is arranged, comes close to the core portion 21 and the center area of and around the turntable 2, thereby leaving a narrow space between the part and the core portion 21. In addition, there is a small gap between the rotational shaft 22 and an inner surface of the through hole through which the rotational shaft 22 penetrates. The narrow space is in gaseous communication with the inside of the case body 20 through the small gap. A purge gas pipe 72 is connected to the upper portion of the case body 20, thereby supplying a purge gas, for example, N₂ gas to the small space through the small gap. Moreover, plural purge gas supplying pipes 73 are connected to the bottom portion 14 of the chamber body 12 below the heater unit 7 along the circumferential direction in order to purge the heater unit housing space with, for example, N₂ gas.

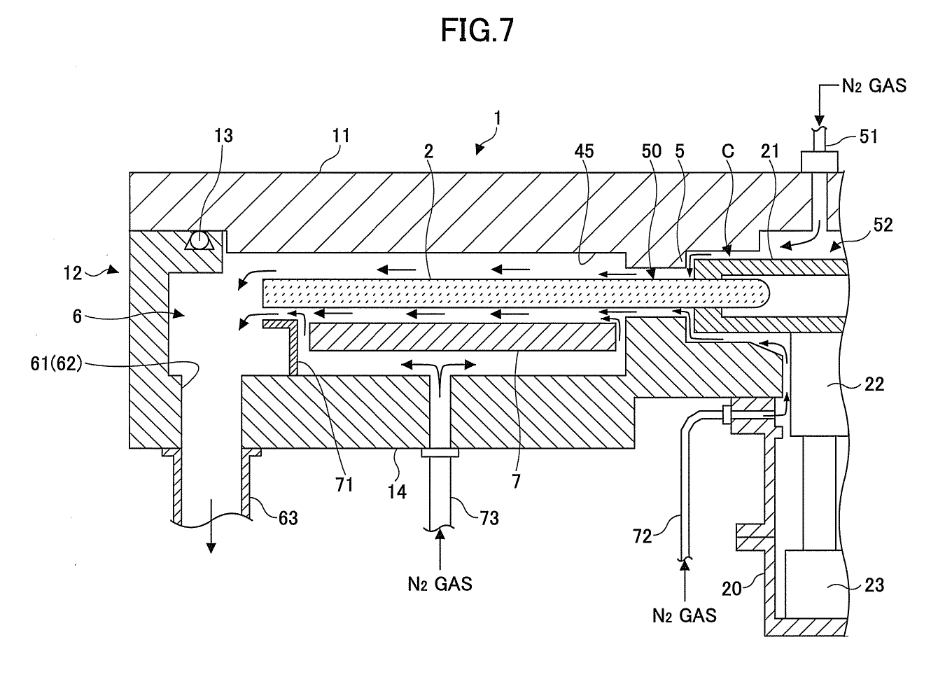

With the purge gas supplying pipes 72, 73, the space extending from the case body 20 through the heater unit housing space is purged with N₂ gas as shown by arrows in FIG. 7. The purge gas is evacuated from the evacuation ports 61, 62 through a gap between the turntable 2 and the cover member 71, and through the evacuation areas 6. With this, the BTBAS (O₃) gas does not flow into the second (first) process area P2 (P1) via the space below the turntable 2. Namely, this purge gas serves as another separation gas.

Referring to FIG. 7, a separation gas supplying pipe 51 is connected to the top center portion of the ceiling plate 11 of the vacuum chamber 1, so that N₂ gas is supplied as a separation gas to a space 52 between the ceiling plate 11 and the core portion 21. The separation gas supplied to the space 52 flows through the thin gap 50 between the protrusion portion 5 and the turntable 2 and then along the top surface of the turntable 2, and reaches the evacuation area 6. Because the space 52 and the gap 50 are filled with the N₂ gas, the reaction gases (BTBAS, O₃) cannot be mixed through the center portion of the turntable 2. In other words, the film deposition apparatus according to this embodiment is provided with a center area C that is defined by the center portion of the turntable 2 and the vacuum chamber 1 in order to isolate the first process area P1 and the second process area P2 and is configured to have an ejection opening that ejects the separation gas toward the top surface of the turntable 2. The ejection opening corresponds to the gap 50 between the protrusion portion 5 and the turntable 2, in the illustrated example.

In addition, a transfer opening 15 is formed in a side wall of the chamber body 12 as shown in FIGS. 2, 3 and 8. Through the transfer opening 15, the wafer W is transferred into or out from the vacuum chamber 1 by a transfer arm 10 (FIGS. 3 and 8). The transfer opening 15 is provided with a gate valve GV (shown only in FIG. 3) by which the transfer opening 15 is opened or closed. When the concave portion 24 of the turntable 2 is in alignment with the transfer opening 15 and the gate valve is opened, the wafer W is transferred into the vacuum chamber 1 and placed in the concave portion 24 as a wafer receiving portion of the turntable 2 from the transfer arm 10. In order to lower/raise the wafer W into/from the concave portion 24, there are provided elevation pins 16 that are raised or lowered through corresponding through holes formed in the concave portion 24 of the turntable 2 by an elevation mechanism (not shown).

The film deposition apparatus according to this embodiment is provided with a controller 100 in order to control operations (including operations in the other embodiments explained later) of the deposition apparatus. The control portion 100 includes a process controller 100a formed of, for example, a computer, a user interface portion 100b, and a memory device 100c. The memory device 100c stores a program for operating the apparatus. The program includes a group of steps for executing an operation of the apparatus described later, and may be installed to the memory device 100c from a storing medium 100d such as a hard disk, a compact disk, a magneto-optical disk, a memory card, a flexible disk, and the like.

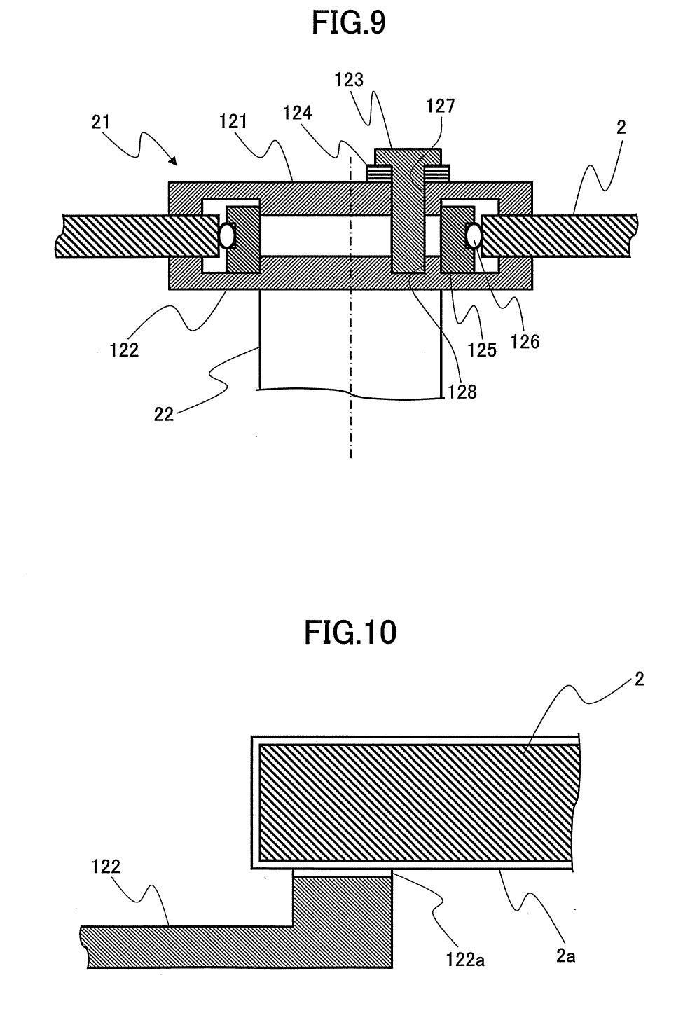

In this embodiment, the turntable 2 is held by the core portion 21, as stated above. Structures of the core portion 21 and the turntable 2, specifically, how the core portion 21 and the turntable 2 are fixed, are explained with reference to FIGS. 9 and 10.

In the film deposition apparatus according to this embodiment, the core portion 21 that holds the turntable 2 has an upper hub 121 as an upper holding member and a lower hub 122 as a lower holding member. The turntable 2 has a circular opening at the center thereof, and this opening is utilized when the turntable 2 is held by the upper hub 121 and the lower hub 122. Specifically, the upper hub 121 and the lower hub 122 are pressed on the turntable 2 from above and below, respectively, so that the turntable 2 is sandwiched and firmly held by the upper hub 121 and the lower hub 122. The upper hub 121 is made of, for example, quartz, and has a hole 127 in or around the center portion of the upper hub 121. The hole 127 allows a bolt (screw) 123 to pass therethrough. The bolt 123 fastens the upper hub 121 with the lower hub 122 in order to hold the turntable 2. In addition, the lower hub 122 is made of, for example, stainless steel, inconel alloy, or the like, and coupled with the rotational shaft 22.

The lower hub 122 is provided with a threaded hole 128 into which the bolt 123 is screwed. As shown in FIG. 10, a ceramic film 122a is formed on an area where the lower hub 122 comes in contact with the turntable 2. The ceramic film 122a may be made of, aluminum oxide (Al₂O₃), yttrium oxide (Y₂O₃), or a mixture of Al₂O₃ and Y₂O₃, by, for example, ceramic spraying. Because the turntable 2 is preferably made of quartz as described below, a difference in a thermal expansion coefficient is relatively large between the lower hub 122 and the turntable 2, which may cause particles to form if the ceramic film 122a is not formed. Namely, without the ceramic film 122a, the lower hub 122 is worn away by scraping in the contact area of the lower hub 122 to the turntable 2, thereby producing metal powders or the like that contaminate the wafer. In addition, if the ceramic film 122a is not formed, the turntable 2 may be damaged or broken in the contact area.

However, such a contamination due to the metal powders or the like and breakage of the turntable 2 are avoided because of the ceramic film 122a formed in the contact area between the lower hub 122 and the turntable 2 in this embodiment. In addition, because the upper hub 121 and the turntable 2 are made of quartz in this embodiment, substantially no problems of contamination and breakage will occur in an area where the upper hub 121 contacts the turntable 2.

Moreover, an upper surface (contacting surface) of the ceramic film 122a formed on the lower hub 122 has a mirror surface in a contact area of the ceramic film 122a to the turntable 2. Similarly, a contact area of the upper hub 121 to the turntable 2 has a mirror surface.

In addition, the turntable 2 may be made of not only quartz but also carbon or the like. A SiC film 2a is formed on the turntable 2 made of carbon or the like, as shown in FIG. 10. Moreover, the areas of the turntable 2 that contact with the upper hub 121 and the lower hub 122 have mirror surfaces.

Because the upper hub 121 is made of quartz and the turntable 2 is made of quartz, or carbon or the like and coated with the SiC film 2a as stated above, ceramic materials contact each other. Therefore, substantially no metal powders are caused due to friction. Especially, when the both contact surfaces have mirror surfaces, a contamination problem is assuredly reduced.

In addition, the ceramic film 122a made of, Al₂O₃, Y₂O₃, or a mixture of Al₂O₃ and Y₂O₃ is formed on the lower hub 122. The turntable 2 is made of quartz, or carbon or the like and coated with the SiC film 2a. Therefore, substantially no metal powders are caused due to friction. Especially, when the both contact surfaces have mirror surfaces, a contamination problem is assuredly reduced.

As stated above, the turntable 2 is held by the upper hub 121 and the lower hub 122 without causing the contamination problem due to the metal powders. Incidentally, the mirror surface may be made by machining such as grinding and polishing.

Incidentally, the lower hub 122 may be made of a ceramic material rather than stainless steel, inconel alloy, or the like. Examples of the ceramic materials, which is preferable to make the lower hub 122 from a viewpoint of toughness, include silicon nitride (SiN), zirconia oxide, or the like. When the lower hub 122 is formed of a ceramic material, there is no need to form the ceramic film 122a on the contact area of the lower hub 122 to the turntable 2.

In addition, the turntable 2 may be made of a ceramic material. In this case, the above advantages are demonstrated without the SiC film 2a formed on the turntable 2. In this embodiment, the upper hub 121 is made of quartz, which has relatively greater resistances against heat and chemical agents, because the upper hub 121 may be heated up to about 300° C. through 400° C. and exposed to corrosive gases in the vacuum chamber 1. Because the upper hub 121 and the turntable 2 are made of quartz in this embodiment, the contact of the upper hub 121 to the turntable 2 is made between the ceramic materials. In addition, when the ceramic film 122a is formed on the lower hub 122, the contact of the lower hub 122 to the turntable 2 is made between the ceramic materials. Moreover, when the lower hub 122 is made of a ceramic material, the contact of the lower hub 122 to the turntable 2 is made between the ceramic materials.

Referring to FIG. 9, the turntable 2 is held by the core portion 21 by inserting the bolt 123 through the hole 127 via a disc spring 124 and screwing the bolt 123 into the screw hole 128 made in the lower hub 122. When the turntable 2 is heated, the heat transmits to the upper hub 121 and the lower hub 122, which may deform the upper hub 121 and the lower hub 122 due to thermal expansion. However, because the dish spring 124 is used in screwing the bolt 123 into the screw hole 128, the deformation may be alleviated by the dish spring 124. Therefore, the upper hub 121 and the lower hub 128 do not suffer from damage or breakage that may be caused from such deformation. Incidentally, the turntable 2 may be held by the upper hub 121 and the lower hub 122 with six bolts 123. In this case, the upper hub 121 has six holes 127, each of which is provided for a corresponding one of six bolts 123, and the lower hub 122 has six screw holes 128, each of which is provided for a corresponding one of the six bolts 123.

In addition, a center ring 125 is provided in the opening formed in the center portion of the turntable 2 so that a center axis of the turntable 2 is in alignment with a rotation axis of the rotational shaft 22, in this embodiment. Because a coil spring 126 is provided between the turntable 2 and the center ring 125 and serves as a buffer for thermal expansion of the turntable 2, the turntable 2 is not damaged, broken, or cracked even when the turntable 2 may be deformed by the heat. Incidentally, because when the turntable 2 is rotated the center ring 125 is also rotated, the rotation axis of the turntable 2 is in alignment with the rotation axis of the center ring 125.

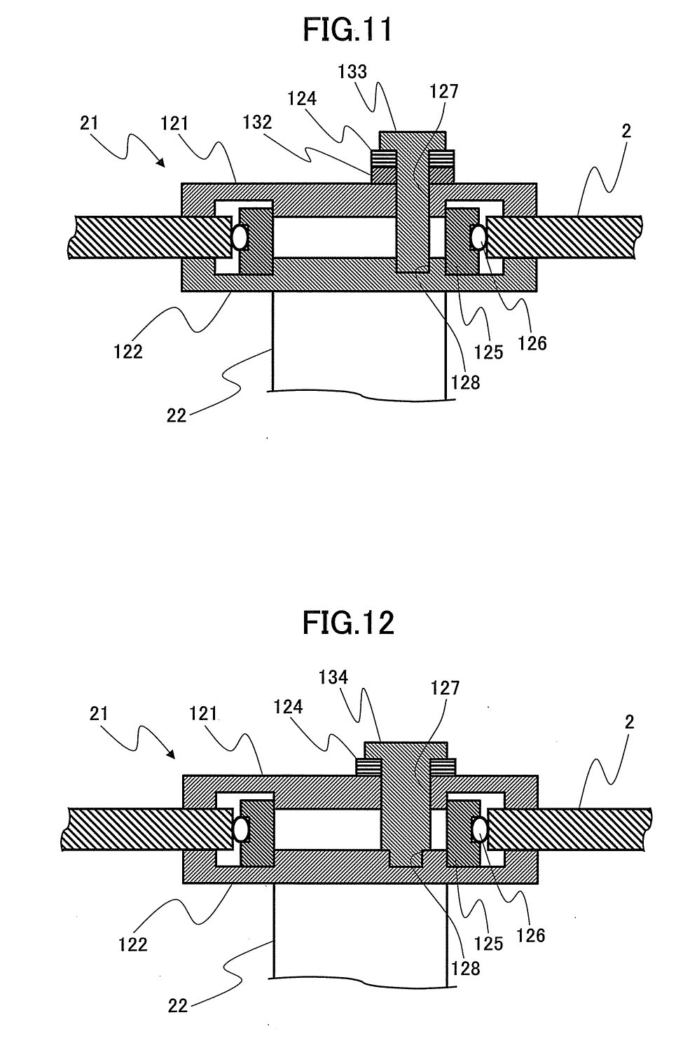

As described above, the turntable 2 is firmly held by the upper hub 121 and the lower hub 122 in such a manner that the upper hub 121 and the lower hub 122 are fastened with each other by the bolt 123, with the turntable 2 between the upper hub 121 and the lower hub 122, in this embodiment. However, as shown in FIG. 11, when a bolt 133 is inserted through the hole 127, a spacer 132 may be used with the disc spring 124. Alternatively, a shoulder bolt 134, which has a thread at a distal end portion to be screwed into the screw hole 128, may be used as shown in FIG. 12. In this case, the bolts 133, 134 are not too tightly screwed into the screw hole 128 and thus the film deposition apparatus of this embodiment can be stably in operation for a longer time.

Next, a process carried out in the film deposition apparatus according to this embodiment is explained. First, the gate valve (not shown) is opened. Then, the wafer W is transferred into the vacuum chamber 1 through the transfer opening 15 by the transfer arm 10 (FIG. 3) and transferred to the concave portion 24. This wafer transferring is carried out by raising/lowering the elevation pins 18 (FIG. 8) through the through-holes in the concave portion 24 when the concave portion 24 stops in a position in alignment with the transfer opening 15.

Such wafer transferring is carried out by intermittently rotating the turntable 2, and five wafers are placed in the corresponding concave portions 24. Next, the gate valve is closed; the vacuum chamber 1 is evacuated to a predetermined pressure; and the wafers W are heated by the heater unit 7 via the turntable 2 while rotating the turntable 2. Specifically, the turntable 2 is heated in advance at a temperature of, for example, 300° C., and the wafers W are heated upon being placed on the turntable 2 (the concave portions 24). After the temperature of the wafers W is confirmed to be the predetermined temperature by a temperature sensor (not shown), the BTBAS gas is supplied from the first reaction gas nozzle 31, the O₃ gas is supplied from the second reaction gas nozzle 32, and the N₂ gas is supplied from the and the separation gas nozzles 41, 42.

Because the wafers W move alternately through the first process area P1 where the first reaction gas nozzle 31 is arranged and the second process area P2 where the second reaction gas nozzle 32 is arranged by the rotation of the turntable 2, the BTBAS gas is adsorbed on the surfaces of the wafers W and then the O₃ gas is adsorbed on the surfaces of the wafers W, thereby oxidizing the BTBAS molecules to form a mono-layer or plural layers of silicon oxide. In such a manner, molecular layers of silicon oxide are accumulatively deposited, and thus the silicon oxide film having a predetermined thickness is formed on the wafers W after predetermined rotations of the turntable 2.

At this time, the N₂ gas serving as the separation gas is supplied from the separation gas supplying pipe 51 (FIG. 7) and ejected along the upper surface of the turntable 2 from the center area C, namely, the gap 50 between the protrusion portion 5 and the turntable 2. In the illustrated example, a space below the second ceiling surface 45, where the reaction gas nozzle 31 (32) is arranged, has a lower pressure than the center area C and the thin space between the first ceiling surface 44 and the turntable 2. This is because the evacuation area 6 is provided next to the space below the ceiling surface 45, and is evacuated through the evacuation ports 61, 62. In addition, this is partly because the thin space is formed so that a pressure difference between the thin space and the space where the reaction gas nozzle 31 (32) is arranged, namely, the first (second) process area P1 (P2) is maintained by the height h.

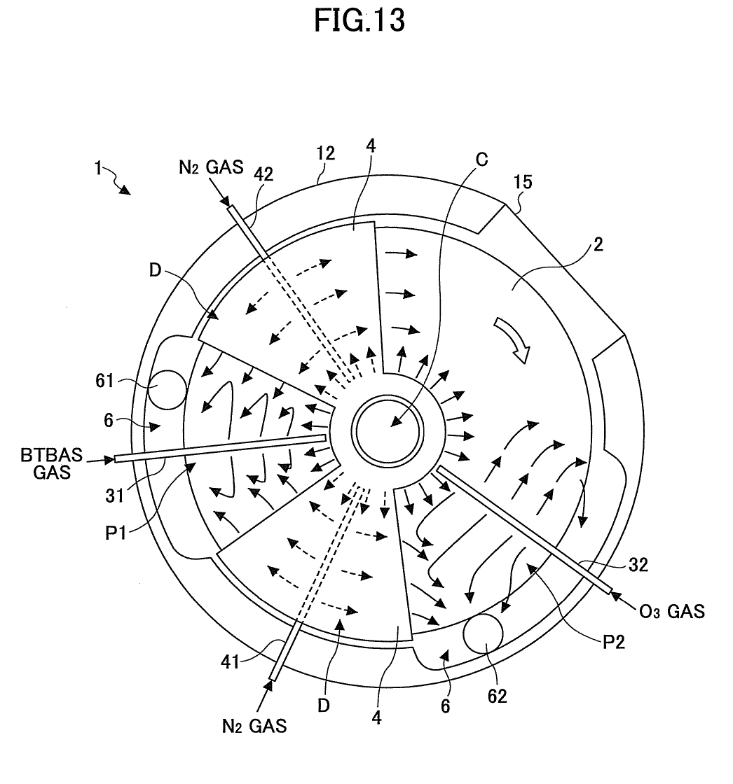

Next, the flow patterns of the gases supplied into the vacuum chamber 1 from the gas nozzles 31, 32, 41, 42 are described in reference to FIG. 13, which schematically shows the flow patterns. As shown, part of the O₃ gas ejected from the second reaction gas nozzle 32 hits and flows along the top surface of the turntable 2 (and the surface of the wafer W) in a direction opposite to the rotation direction of the turntable 2. Then, the O₃ gas is pushed back by the N₂ gas flowing along the rotation direction, and changes the flow direction toward the edge of the turntable 2 and the inner circumferential wall of the chamber body 12. Finally, this part of the O₃ gas flows into the evacuation area 6 and is evacuated from the vacuum chamber 1 through the evacuation port 62.

Another part of the O₃ gas ejected from the second reaction gas nozzle 32 hits and flows along the top surface of the turntable 2 (and the surface of the wafers W) in the same direction as the rotation direction of the turntable 2. This part of the O₃ gas mainly flows toward the evacuation area 6 due to the N₂ gas flowing from the center portion C and suction force through the evacuation port 62. On the other hand, a small portion of this part of the O₃ gas flows toward the separation area D located downstream of the rotation direction of the turntable 2 in relation to the second reaction gas nozzle 32 and may enter the gap between the ceiling surface 44 and the turntable 2. However, because the height h of the thin space is designed so that the O₃ gas is impeded from flowing into the gap at film deposition conditions intended, the small portion of the O₃ gas cannot flow into the gap. Even when a small fraction of the O₃ gas flows into the gap, the fraction of the O₃ gas cannot flow farther into the separation area D, because the fraction of the O₃ gas can be pushed backward by the N₂ gas ejected from the separation gas nozzle 41. Therefore, substantially all the part of the O₃ gas flowing along the top surface of the turntable 2 in the rotation direction flows into the evacuation area 6 and is evacuated by the evacuation port 62, as shown in FIG. 9.

Similarly, the BTBAS gas ejected from the first reaction gas nozzle 31 to flow along the top surface of the turntable 2 (and the surface of the wafers W) in the rotation direction of the turntable 2 and the opposite direction cannot flow into the gaps below the convex portions 4 located upstream and downstream of the rotation direction, respectively. Alternatively, even when a fraction of the BTBAS gas enters the gaps, the fraction of the BTBAS gas is pushed backward to the process areas P1, P2. Then, the BTBAS gas flows into the evacuation area 6 between the circumference of the turntable 2 and the inner circumferential wall of the vacuum chamber 1, and is evacuated through the evacuation port 61 along with the N₂ gas ejected from the center area C.

As stated above, the separation areas D may prevent the BTBAS gas and the O₃ gas from flowing thereinto, or may greatly reduce the amount of the BTBAS gas and the O₃ gas flowing thereinto, or may push the BTBAS gas and the O₃ gas backward. On the other hand, the BTBAS molecules and the O₃ molecules adsorbed on the wafer W are allowed to go through the separation area D (below the lower ceiling surface 44), contributing to the film deposition.

Additionally, the BTBAS gas in the first process area P1 (the O₃ gas in the second process area P2) is impeded from flowing into the center area C, because the separation gas is ejected toward the outer circumferential edge of the turntable 2 from the center area C, as shown in FIGS. 7 and 13. Even if a fraction of the BTBAS gas in the first process area P1 (the O₃ gas in the second process area P2) flows into the center area C, the BTBAS gas (the O₃ gas) is pushed backward, so that the BTBAS gas in the first process area P1 (the O₃ gas in the second process area P2) is impeded from flowing into the second process area P2 (the first process area P1) through the center area C.

Moreover, the BTBAS gas in the first process area P1 (the O₃ gas in the second process area P2) is impeded from flowing into the second process area P2 (the first process area P1) through the space between the turntable 2 and the inner circumferential wall of the chamber body 12. This is because the bent portion 46 is formed downward from the convex portion 4 so that the gaps between the bent portion 46 and the turntable 2 and between the bent portion 46 and the inner circumferential wall of the chamber body 12 are as small as the height h of the ceiling surface 44 of the protrusion portion 5, thereby substantially avoiding gaseous communication between the two process areas P1, P2, as stated above. Therefore, the two separation areas D separate the first process area P1 and the second process area P2, and the BTBAS gas and the O₃ gas are evacuated from the evacuation ports 61, 62, respectively. As a result, the reaction gases (BTBAS, O₃) are not mixed in an atmosphere in the vacuum chamber 1. Moreover, because the space below the turntable 2 is purged with the N₂ gas, the BTBAS gas, for example, flowing into the evacuation area 6 cannot flow through the space below the turntable 2 into the second process area P2 where the O₃ gas is supplied.

After the film deposition is completed in the above manner, the wafers W are transferred out from the vacuum chamber 1 in accordance with procedures opposite to the procedures for transferring the wafers W into the vacuum chamber 1.

An example of process parameters preferable in the film deposition apparatus according to this embodiment is listed in the following. A rotational speed of the turntable 2 is 1 through 500 rpm (in the case of the wafer W having a diameter of 300 mm); a pressure in the vacuum chamber 1 is about 1.067 kPa (8 Torr); a temperature of the wafers W is about 350° C.; a flow rate of the DCS gas is 100 sccm; a flow rate of the NH₃ gas is about 10000 sccm; a flow rate of the N₂ gas from the separation gas nozzles 41, 42 is about 20000 sccm; and a flow rate of the N₂ gas from the separation gas supplying pipe 51 at the center of the vacuum chamber 1 is about 5000 sccm. In addition, the number of cycles of alternately supplying the reaction gases to the wafers W, namely, the number of times when the wafers W alternately pass through the process area P1 and the process area P2 is about 600, though changed depending on the film thickness required.

According to the film deposition apparatus of this embodiment, because the film deposition apparatus has the separation areas D including the low ceiling surface 44 between the first process area P1, to which the BTBAS gas is supplied from the first reaction gas nozzle 31, and the second process area P2, to which the O₃ gas is supplied from the second reaction gas nozzle 32, the BTBAS gas (the O₃ gas) is prevented from flowing into the second process area P2 (the first process area P1) and being mixed with the O₃ gas (the BTBAS gas). Therefore, an MLD (or ALD) mode deposition of silicon dioxide is assuredly performed by rotating the turntable 2 on which the wafers W are placed in order to allow the wafers W to pass through the first process area P1, the separation area D, the second process area P2, and the separation area D. In addition, the separation areas D further include the separation gas nozzles 41, 42 from which the N₂ gases are ejected in order to further assuredly prevent the BTBAS gas (the O₃ gas) from flowing into the second process area P2 (the first process area P1) and being mixed with the O₃ gas (the BTBAS gas). Moreover, because the vacuum chamber 1 of the film deposition apparatus according to this embodiment has the center area C having the ejection holes from which the N₂ gas is ejected, the BTBAS gas (the O₃ gas) is prevented from flowing into the second process area P2 (the first process area P1) through the center area C and being mixed with the O₃ gas (the BTBAS gas). Furthermore, because the BTBAS gas and the O₃ gas are not mixed, almost no deposits of silicon dioxide are made on the turntable 2, thereby reducing particle problems.

Incidentally, although the turntable 2 has the five concave portions 24 and five wafers W placed in the corresponding concave portions 24 can be processed in one run in this embodiment, only one wafer W may be placed in one of the five concave portions 24, or the turntable 2 may have only one concave portion 24.

The reaction gases that may be used in the film deposition apparatus according to an embodiment of the present invention are dichlorosilane (DCS), hexachlorodisilane (HCD), Trimethyl Aluminum (TMA), tris(dimethyl amino) silane (3DMAS), tetrakis-ethyl-methyl-amino-hafnium (TEMHf), bis(tetra methyl heptandionate) strontium (Sr(THD)₂) (methyl-pentadionate)(bis-tetra-methyl-heptandionate) titanium (Ti(MPD)(THD)), tetrakis-ethyl-methyl-amino-zirconium (TEMAZr), monoamino-silane, or the like.

Because a larger centrifugal force is applied to the gases in the vacuum chamber 1 at a position closer to the outer circumference of the turntable 2, the BTBAS gas, for example, flows toward the separation area D at a higher speed in the position closer to the outer circumference of the turntable 2. Therefore, the BTBAS gas is more likely to enter the gap between the ceiling surface 44 and the turntable 2 in the position closer to the circumference of the turntable 2. Because of this situation, when the convex portion 4 has a greater width (a longer arc) toward the circumference, the BTBAS gas cannot flow farther into the gap and mix with the O₃ gas. In view of this, it is preferable for the convex portion 4 to have a sector-shaped top view, as explained in the above embodiment.

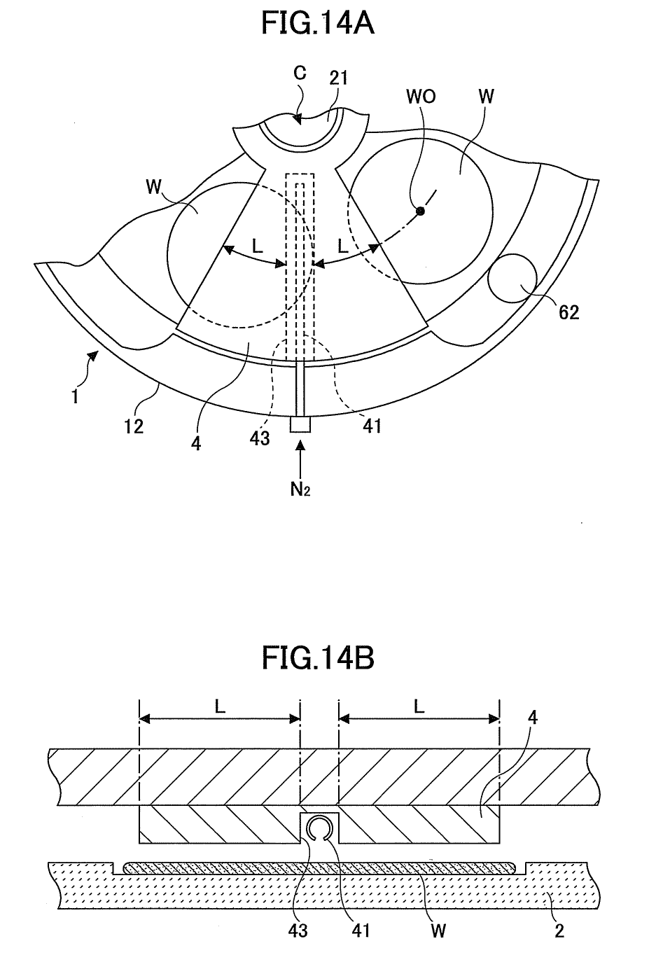

The size of the convex portion 4 (or the ceiling surface 44) is exemplified again below. Referring to FIGS. 14A and 14B, the ceiling surface 44 that creates the thin space in both sides of the separation gas nozzle 41 (42) may preferably have a length L ranging from about one-tenth of a diameter of the wafer W through about a diameter of the wafer W, preferably, about one-sixth or more of the diameter of the wafer W along an arc that corresponds to a route through which a wafer center WO passes. Specifically, the length L is preferably about 50 mm or more when the wafer W has a diameter of 300 mm. When the length L is small, the height h of the thin space between the ceiling surface 44 and the turntable 2 (wafer W) has to be accordingly small in order to effectively prevent the reaction gases from flowing into the thin space. However, when the length L becomes too small and thus the height h has to be extremely small, the turntable 2 may hit the ceiling surface 44, which may cause wafer breakage and wafer contamination through particle generation. Therefore, measures to dampen vibration of the turntable 2 or measures to stably rotate the turntable 2 are required in order to avoid the turntable 2 hitting the ceiling surface 44. On the other hand, when the height h of the thin space is kept relatively greater while the length L is small, a rotational speed of the turntable 2 has to be lower in order to avoid the reaction gases flowing into the thin gap between the ceiling surface 44 and the turntable 2, which is rather disadvantageous in terms of production throughput. From these considerations, the length L of the ceiling surface 44 along the arc corresponding to the route of the wafer center WO is preferably about 50 mm or more when the wafers W having a diameter of 300 mm are processed, as stated above. However, the size of the convex portion 4 or the ceiling surface 44 is not limited to the above, but may be adjusted depending on the process parameters and the size of the wafer to be used. In addition, as clearly understood from the above explanation, the height h of the thin space may be adjusted depending on an area of the ceiling surface 44 in addition to the process parameters and the size of the wafer to be used, as long as the thin space has a height that allows the separation gas to flow from the separation area D through the process area P1 (P2).

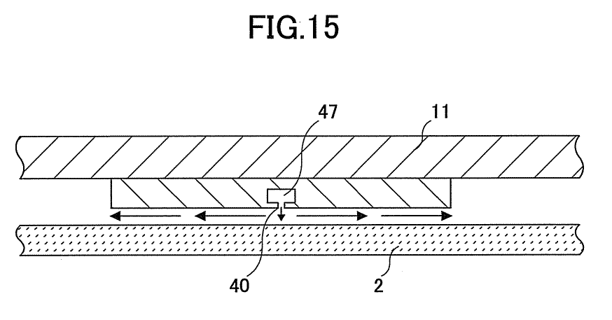

The separation gas nozzle 41 (42) is located in the groove portion 43 formed in the convex portion 4 and the lower ceiling surfaces 44 are located at both sides of the separation gas nozzle 41 (42) in the above embodiment. However, as shown in FIG. 15, a conduit 47 extending along the radial direction of the turntable 2 may be made inside the convex portion 4, instead of the separation gas nozzle 41 (42), and plural holes 40 may be formed along the longitudinal direction of the conduit 47 so that the separation gas (N₂ gas) may be ejected from the plural holes 40 in other embodiments.

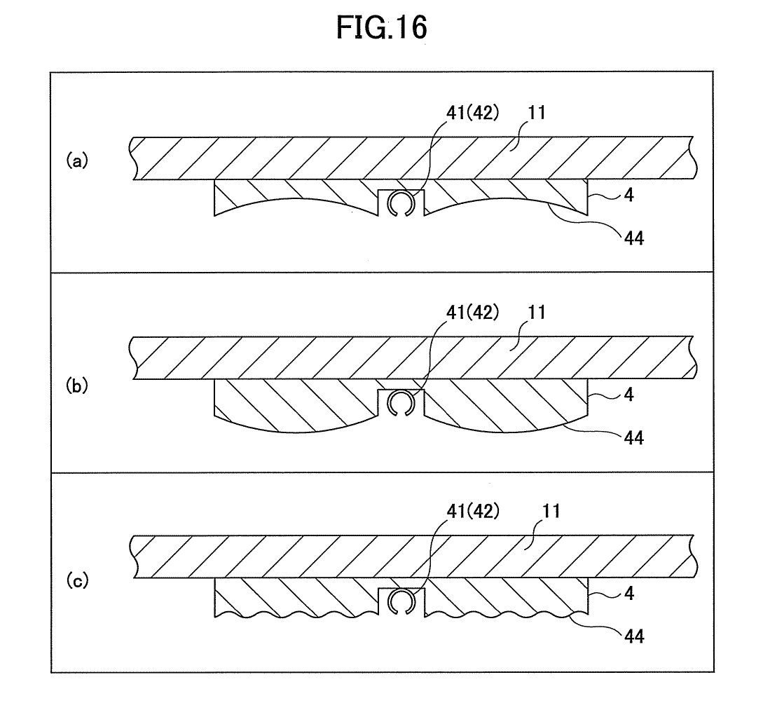

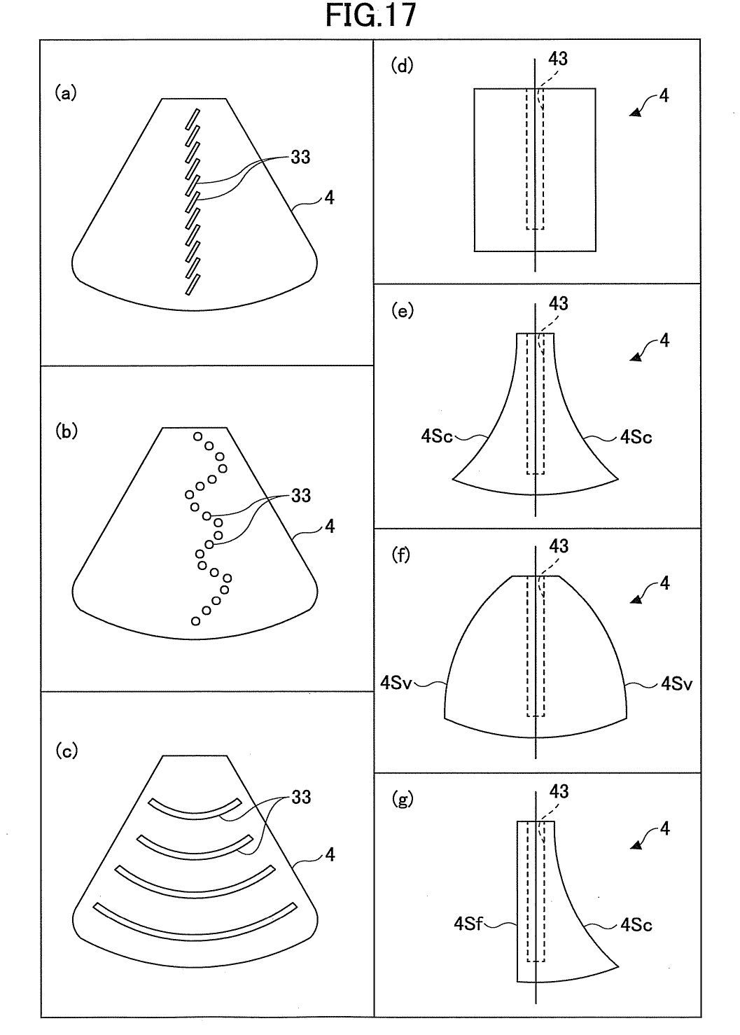

The ceiling surface 44 of the separation area D is not necessarily flat in other embodiments. For example, the ceiling surface 44 may be concavely curved as shown in subsection (a) of FIG. 16, convexly curved as shown in subsection (b) of FIG. 16, or corrugated as shown in subsection (c) of FIG. 16.

In addition, the convex portion 4 may be hollow and the separation gas may be introduced into the hollow convex portion 4. In this case, the plural gas ejection holes 33 may be arranged as shown in subsections (a) through (c) of FIG. 17.

Referring to subsection (a) of FIG. 13, the plural gas ejection holes 33 each have a shape of a slanted slit. These slanted slits (gas ejection holes 33) are arranged to be partially overlapped with an adjacent slit along the radial direction of the turntable 2. In subsection (b) of FIG. 13, the plural gas ejection holes 33 are circular. These circular holes (gas ejection holes 33) are arranged along a winding line that extends in the radial direction as a whole. In subsection (c) of FIG. 13, each of the plural gas ejection holes 33 has the shape of an arc-shaped slit. These arc-shaped slits (gas ejection holes 33) are arranged at predetermined intervals in the radial direction.

While the convex portion 4 has the sector-shaped top view shape in this embodiment, the convex portion 4 may have a rectangle top view shape as shown in subsection (d) of FIG. 17, or a square top view shape in other embodiments. Alternatively, the convex portion 4 may be sector-shaped as a whole in the top view and have concavely curved side surfaces 4Sc, as shown in subsection (e) of FIG. 17. In addition, the convex portion 4 may be sector-shaped as a whole in the top view and have convexly curved side surfaces 4Sv, as shown in subsection (d) of FIG. 17. Moreover, an upstream portion of the convex portion 4 relative to the rotation direction of the turntable 2 (FIG. 1) may have a concavely curved side surface 4Sc and a downstream portion of the convex portion 4 relative to the rotation direction of the turntable 2 (FIG. 1) may have a flat side surface 4Sf, as shown in subsection (g) of FIG. 17. Incidentally, dotted lines in subsections (d) through (g) of FIG. 13 represent the groove portions 43 (FIGS. 4A and 4B). In these cases, the separation gas nozzle 41 (42), which is housed in the groove portion 43, extends from the center portion of the vacuum chamber 1, for example, from the protrusion portion 5.

The heater unit 7 for heating the wafers W is configured to have a lamp heating element instead of the resistance heating element. In addition, the heater unit 7 may be located above the turntable 2, or above and below the turntable 2.

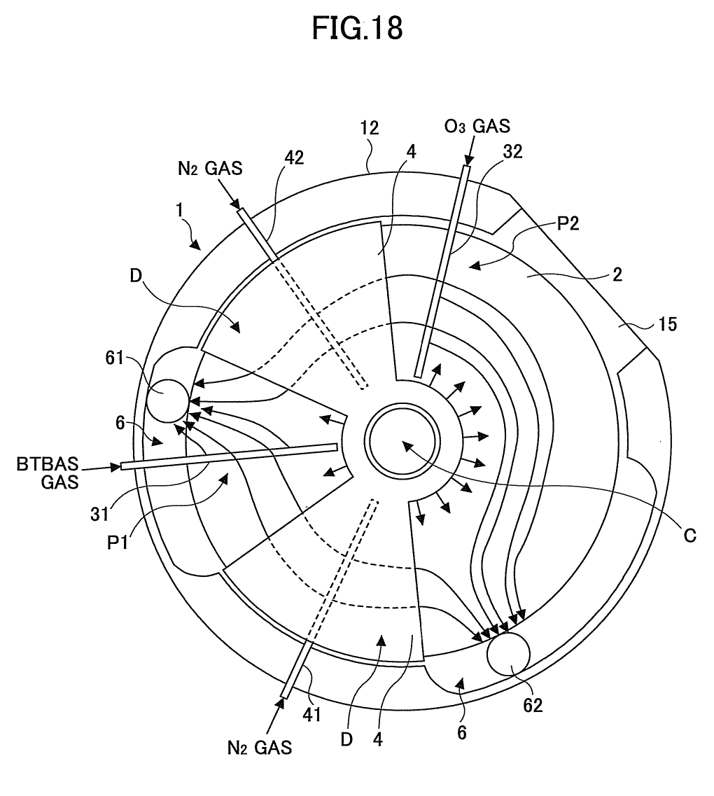

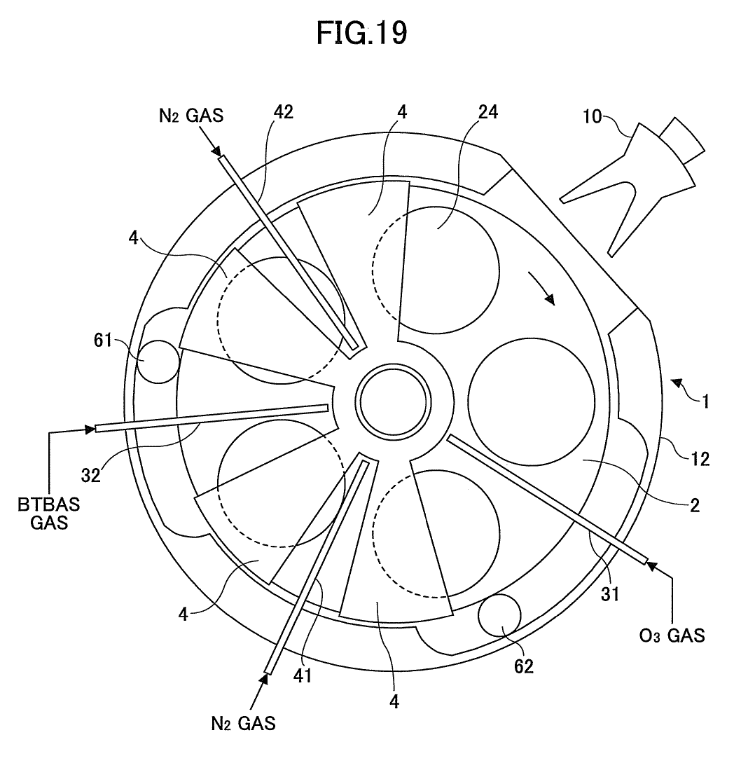

Another arrangement of the first and the second process areas P1, P2 and the separation area D is exemplified in the following. Referring to FIG. 18, the second reaction gas nozzle 32 for supplying the second reaction gas (e.g., O₃ gas) is located upstream relative to the rotation direction of the turntable 12 with respect to the transfer opening 15, or between the separation gas nozzle 42 and the transfer opening 15. Even in such an arrangement, the gases ejected from the nozzle 31, 32, 41, 42 and the center area C flow generally along arrows shown in FIG. 18, so that the first reaction gas and the second reaction gas cannot be mixed. Therefore, a proper ALD (or MLD) mode film deposition can be realized by such an arrangement.

In addition, the separation area D may be configured by attaching two sector-shaped plates on the bottom surface of the ceiling plate 1 by screws so that the two sector-shaped plates are located on both sides of the separation gas nozzle 41 (42), as stated above. FIG. 15 is a plan view of such a configuration. In this case, the distance between the convex portion 4 and the separation gas nozzle 41 (42), and the size of the convex portion 4 can be determined taking into consideration ejection rates of the separation gas and the reaction gas in order to effectively provide the separation function of the separation area D.

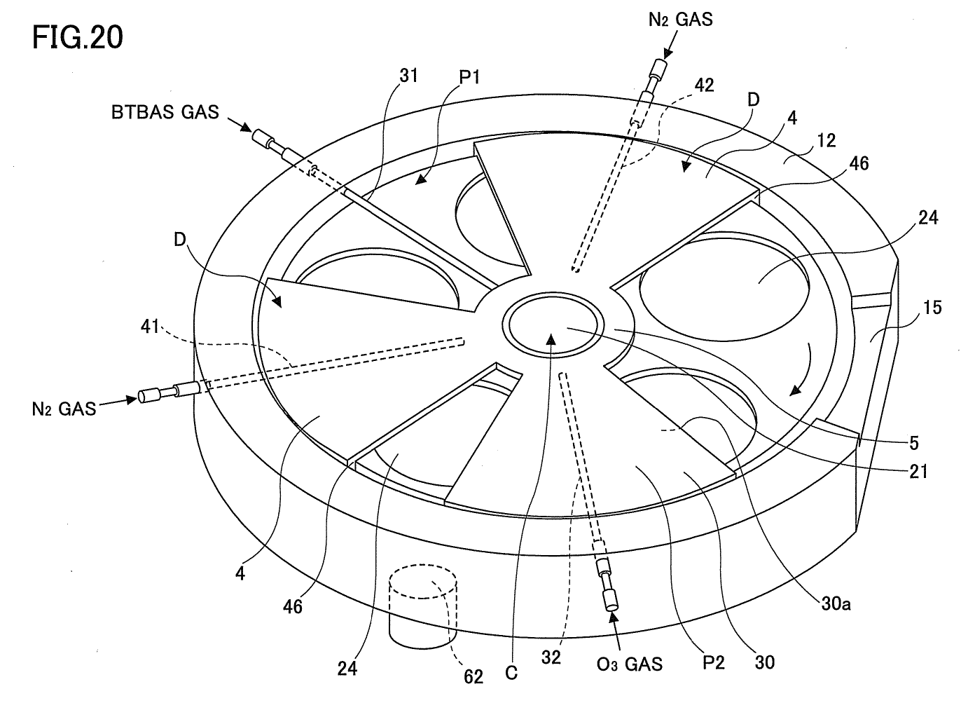

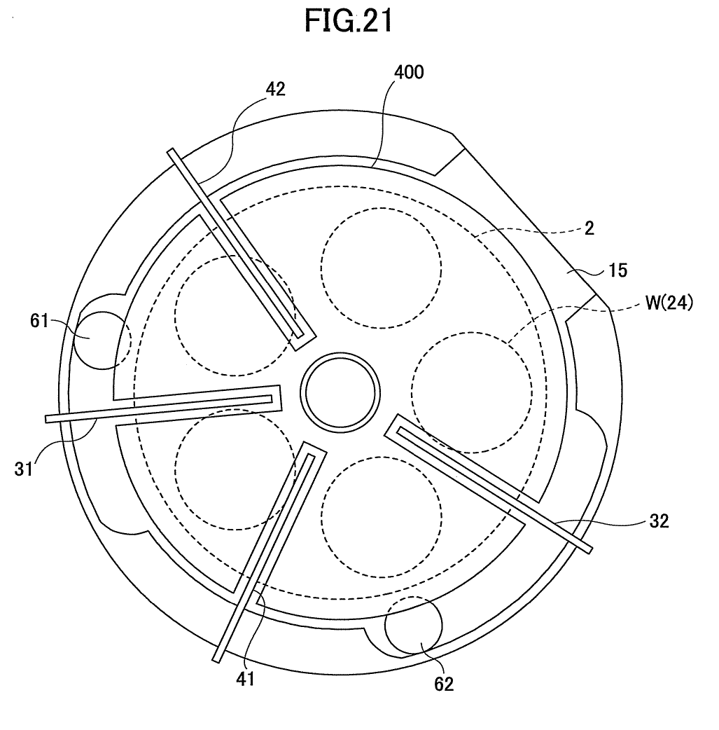

In the above embodiment, the first process area P1 and the second process area P2 correspond to the areas having the ceiling surface 45 higher than the ceiling surface 44 of the separation area D. However, at least one of the first process area P1 and the second process area P2 may have another ceiling surface that opposes the turntable 2 at both sides of the reaction gas supplying nozzle 31 (32) and is lower than the ceiling surface 45 in order to prevent gas from flowing into a gap between the ceiling surface concerned and the turntable 2. This ceiling surface, which is lower than the ceiling surface 45, may be as low as the ceiling surface 44 of the separation area D. FIG. 20 shows an example of such a configuration. As shown, a sector-shaped convex portion 30 is located in the second process area P2, where O₃ gas is adsorbed on the wafer W, and the reaction gas nozzle 32 is located in the groove portion (not shown) formed in the convex portion 30. In other words, this second process area P2 shown in FIG. 20 is configured in the same manner as the separation area D, while the gas nozzle is used in order to supply the reaction gas. In addition, the convex portion 30 may be configured as a hollow convex portion, an example of which is illustrated in subsections (a) through (c) of FIG. 17.

Moreover, the ceiling surface, which is lower than the ceiling surface 45 and as low as the ceiling surface 44 of the separation area D, may be provided for both reaction gas nozzles 31, 32 and extended to reach the ceiling surfaces 44 in other embodiments, as shown in FIG. 21, as long as the low ceiling surfaces 44 are provided on both sides of the reaction gas nozzle 41 (42). In other words, another convex portion 400 may be attached on the bottom surface of the ceiling plate 11, instead of the convex portion 4. The convex portion 400 has a shape of substantially a circular plate, opposes substantially the entire top surface of the turntable 2, has four slots where the corresponding gas nozzles 31, 32, 41, 42 are housed, the slots extending in a radial direction, and leaves a thin space below the convex portion 400 in relation to the turntable 2. A height of the thin space may be comparable with the height h stated above. When the convex portion 400 is employed, the reaction gas ejected from the reaction gas nozzle 31 (32) diffuses to both sides of the reaction gas nozzle 31 (32) below the convex portion 400 (or in the thin space) and the separation gas ejected from the separation gas nozzle 41 (42) diffuses to both sides of the separation gas nozzle 41 (42). The reaction gas and the separation gas flow into each other in the thin space and are evacuated through the evacuation port 61 (62). Even in this case, the reaction gas ejected from the reaction gas nozzle 31 cannot be mixed with the other reaction gas ejected from the reaction gas nozzle 32, thereby realizing a proper ALD (or MLD) mode film deposition.

Incidentally, the convex portion 400 may be configured by combining the hollow convex portions 4 shown in any of subsections (a) through (c) of FIG. 17 in order to eject the reaction gases and the separation gases from the corresponding ejection holes 33 in the corresponding hollow convex portions 4 without using the gas nozzles 31, 32, 41, 42 and the slits 400a.

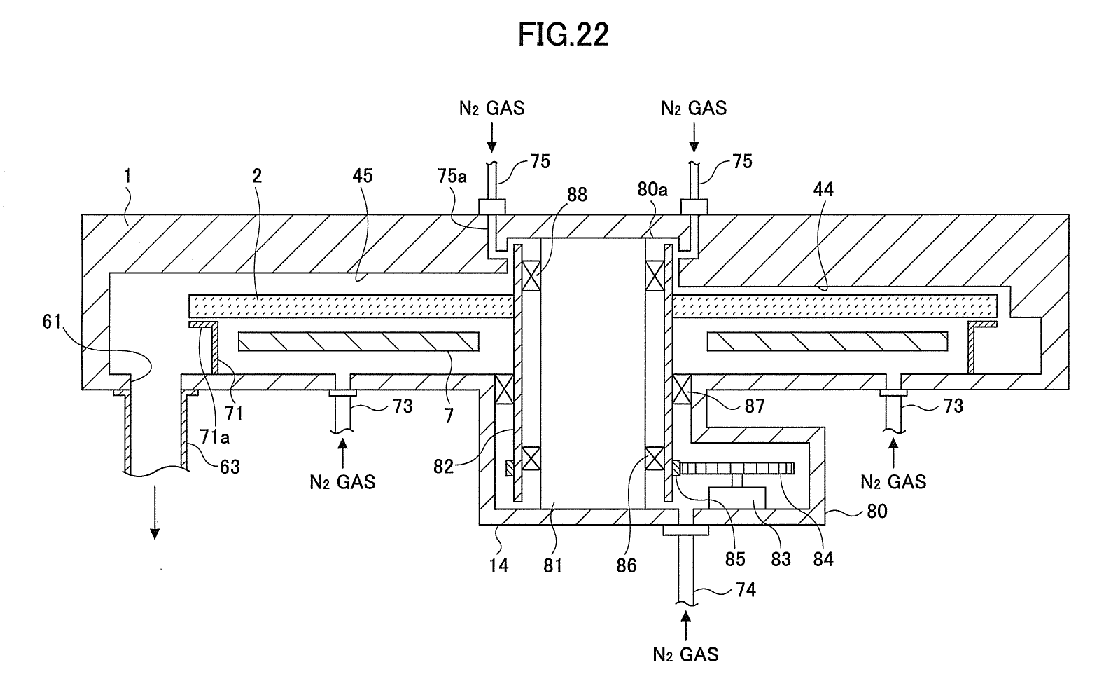

In the above embodiments, the rotational shaft 22 for the turntable 2 is located in the center of the vacuum chamber 1 and the space defined by the center portion of the turntable 2 and the ceiling plate 11 is purged with the separation gas. However, the film deposition apparatus according to another embodiment may be configured as shown in FIG. 22. In the film deposition apparatus of FIG. 22, the bottom portion 14 of the chamber body 12 is extended downward at the center and a housing space 80 is formed in the extended area. In addition, an upper inner surface (ceiling surface) of the vacuum chamber 1 is dented upward at the center and a concave portion 80a is formed in the dented area. Moreover, a pillar 81 is provided so that the pillar 81 extends from a bottom surface of the housing space 80 through an upper inner surface of the concave portion 80a. This configuration can prevent a gas mixture of the DCS gas from the first reaction gas nozzle 31 and the NH₃ gas from the activated gas injector 32 from flowing through the center area of the vacuum chamber 1.

Next, a driving mechanism for the turntable 2 is explained. A rotation sleeve 82 is provided so that the rotation sleeve 82 coaxially surrounds the pillar 81. The turntable 2, which is a ring shape, is attached on the outer circumferential surface of the rotation sleeve 82. In addition, a motor 83 is provided in the housing space 80 and a gear 84 is attached to a driving shaft extending from the motor 83. The gear 84 engages with a gear 85 formed or attached on an outer circumferential surface of the rotation sleeve 82, and drives the rotation sleeve 82 via the gear 85 when the motor 83 is energized, thereby rotating the turntable 2. Reference numerals “86”, “87”, and “88” in FIG. 27 represent bearings. In addition, a gas purge supplying pipe 74 is connected to the bottom of the housing space 80, and purge gas supplying pipes 75 are connected to an upper portion of the vacuum chamber 1. The purge gas supplying pipes 75 supply purge gas to the space defined by an inner side wall of the concave portion 80a and the upper portion of the rotation sleeve 82. While two purge gas supplying pipes 75 are shown in FIG. 22, three or more purge gas supplying pipes 75 may be provided, in other embodiments. The number of the purge gas supplying pipes 75 and their arrangements may be determined so that the DCS gas and the NH₃ gas are not mixed through an area near the rotation sleeve 82.

In the embodiment illustrated in FIG. 22, a space between the side wall of the concave portion 80a and the upper end portion of the rotation sleeve 82 corresponds to the ejection hole for ejecting the separation gas. In addition, the center area is configured with the ejection hole, the rotation sleeve 82, and the pillar 81.

Although the two kinds of reaction gases are used in the film deposition apparatus according to the above embodiment, three or more kinds of reaction gases may be used in another film deposition apparatus according to other embodiments of the present invention. In this case, a first reaction gas nozzle, a separation gas nozzle, a second reaction gas nozzle, a separation gas nozzle, and a third reaction gas nozzle may be located in this order at predetermined angular intervals, each nozzle extending along the radial direction of the turntable 2. Additionally, the separation areas D including the corresponding separation gas nozzles are configured in the same manner as explained above.

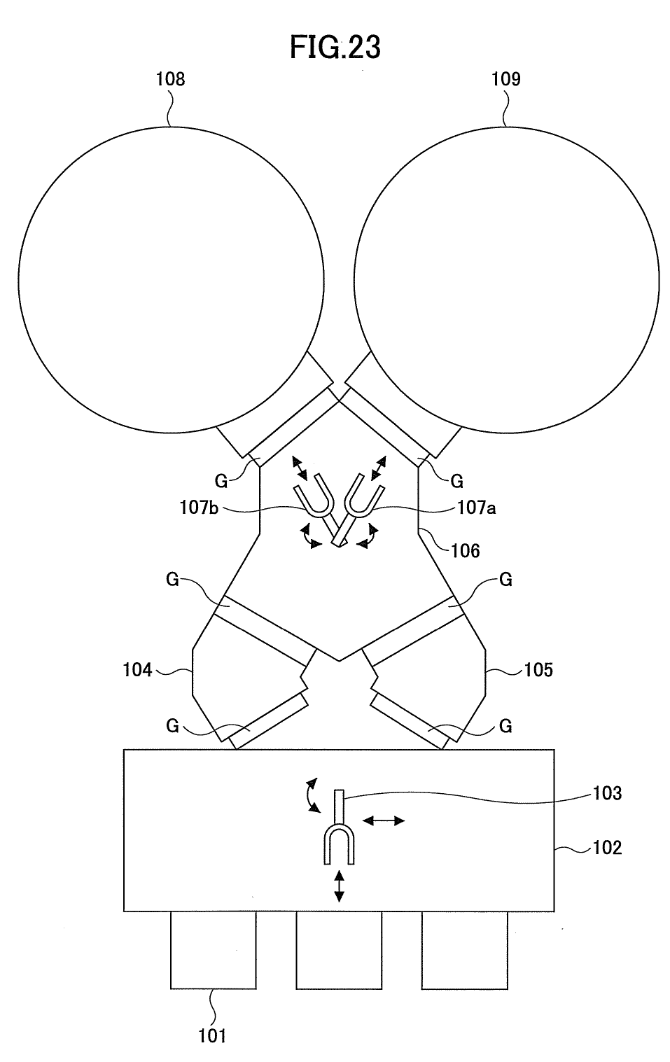

The film deposition apparatus according to embodiments of the present invention may be integrated into a wafer process apparatus, an example of which is schematically illustrated in FIG. 23. In this drawing, reference numeral “101” indicates a closed-type wafer transfer cassette such as a Front Opening Unified Pod (FOUP) that houses, for example, 25 wafers; reference numeral “102” indicates an atmospheric transfer chamber where a transfer arm 103 is arranged; reference numerals “104” and “105” indicate load lock chambers (preparation chambers) whose inner pressure is changeable between vacuum and an atmospheric pressure; reference numeral “106” indicates a vacuum transfer chamber where two transfer arms 107a, 107b are provided; and reference numerals “108” and “109” indicate film deposition apparatuses according to an embodiment of the present invention. The vacuum transfer chamber 106 is hermetically connected to the load lock chambers 104, 105 and the film deposition apparatuses 108, 109. The wafer transfer cassette 101 is brought into a transfer port including a stage (not shown); a cover of the wafer transfer cassette 101 is opened by an opening/closing mechanism (not shown); and the wafer is taken out from the wafer transfer cassette 101 by the transfer arm 103. Next, the wafer is transferred to the load lock vacuum chamber 104 (105). After the load lock vacuum chamber 104 (105) is evacuated to a predetermined reduced pressure, the wafer is transferred further to one of the film deposition apparatuses 108, 109 through the vacuum transfer vacuum chamber 106 by the transfer arm 107a (107b). In the film deposition apparatus 108 (109), a film is deposited on the wafer in such a manner as described above. Because the wafer process apparatus has two film deposition apparatuses 108, 109 that can house five wafers at a time, the ALD (or MLD) mode deposition can be performed at high throughput.

While the present invention has been described in reference to the foregoing embodiments, the present invention is not limited to the disclosed embodiments, but may be modified or altered within the scope of the accompanying claims.

What is claimed is:

1. A film deposition apparatus for depositing a film on a substrate by carrying out a cycle of alternately supplying at least two kinds of reaction gases that react with each other to the substrate to produce a layer of a reaction product in a vacuum chamber, the film deposition apparatus comprising:
a turntable rotatably provided in the vacuum chamber;
a substrate receiving portion that is provided in the turntable and the substrate is placed in;
a first reaction gas supplying portion configured to supply a first reaction gas to a surface having the substrate receiving portion;
a second reaction gas supplying portion configured to supply a second reaction gas to the surface having the substrate receiving portion, the second reaction gas supplying portion being separated from the first reaction gas supplying portion along a rotation direction of the turntable;
a separation area located along the rotation direction between a first process area in which the first reaction gas is supplied and a second process area in which the second reaction gas is supplied, wherein the separation area includes a separation gas supplying portion that supplies a first separation gas, and a ceiling surface that creates in relation to the turntable a thin space in which the first separation gas may flow from the separation area to the process area sides in relation to the rotation direction;
a center area that is located substantially in a center portion of the vacuum chamber in order to separate the first process area and the second process area, and has an ejection hole that ejects a second separation gas along the surface having the substrate receiving area;
an evacuation opening provided in the vacuum chamber in order to evacuate the vacuum chamber;
an upper holding member that may be pressed on an upper center portion of the turntable and is configured of one of quartz and a ceramic material; and
a lower holding member that may be pressed on a lower center portion of the turntable in order to rotatably hold the turntable in cooperation with the upper holding member.

2. The film deposition apparatus of claim 1, wherein the lower holding member is configured of a ceramic material.

3. The film deposition apparatus of claim 1, wherein a ceramic film is formed on at least an area of the lower holding member, the area contacting the turntable.

4. The film deposition apparatus of claim 3, wherein the ceramic film formed on at lease the area of lower holding member has an upper mirror surface.

5. The film deposition apparatus of claim 1, wherein ceramic films are formed on areas of the turntable that contact the upper holding member and the lower holding member, respectively.

6. The film deposition apparatus of claim 5, wherein the ceramic films formed on the areas of the turntable that contact the upper holding member and the lower holding member, respectively have upper mirror surfaces.

7. The film deposition apparatus of claim 3, wherein the ceramic film is made of one of aluminum oxide, yttrium oxide, and a mixture of aluminum oxide and yttrium oxide.

8. The film deposition apparatus of claim 1, wherein the turntable is made of one of quartz, carbon, and a ceramic material.

9. The film deposition apparatus of claim 1, wherein the evacuation opening is located lower than the turntable.

10. The film deposition apparatus of claim 1, wherein the turntable has an opening at a center of the turntable;
wherein the upper holding member and the lower holding member are arranged to cover the opening;
wherein the upper holding member has an through hole;
wherein the lower holding member has a screw hole; and
wherein a bolt is inserted via a disc spring from the through hole and screwed into the screw hole through the opening, thereby holding the turntable.

11. The film deposition apparatus of claim 1, wherein the opening has a circular shape,
wherein a center ring having a rotational axis in agreement with an rotation axis of the turntable is provided in the circular opening, and
wherein a coil spring is provided between the center ring and an inner circumferential surface of the circular opening.

12. The film deposition apparatus of claim 1, wherein the substrate receiving area has a circular concave shape, and
wherein an upper surface of the substrate placed in the substrate receiving area is located lower than or at the same elevation as an upper surface of the turntable.

13. The film deposition apparatus of claim 1, wherein the vacuum chamber has a transfer opening through which the substrate to be processed is transferred, the transfer opening being provided in a side wall of the vacuum chamber and openable/closable with a gate valve.

14. The film deposition apparatus of claim 1, further comprising a heating unit configured to heat the turntable.

15. A film deposition apparatus for depositing a film on a substrate by carrying out a cycle of alternately supplying at least two kinds of reaction gases that react with each other to the substrate to produce a layer of a reaction product in a vacuum chamber, the film deposition apparatus comprising:
a turntable rotatably provided in the vacuum chamber;
a substrate receiving portion that is provided in the turntable and the substrate is placed in;
a first reaction gas supplying portion configured to supply a first reaction gas to a surface having the substrate receiving portion;
a second reaction gas supplying portion configured to supply a second reaction gas to the surface having the substrate receiving portion, the second reaction gas supplying portion being separated from the first reaction gas supplying portion along a rotation direction of the turntable;
a separation area located along the rotation direction between a first process area in which the first reaction gas is supplied and a second process area in which the second reaction gas is supplied, wherein the separation area includes a separation gas supplying portion that supplies a first separation gas, and a ceiling surface that creates in relation to the turntable a thin space in which the first separation gas may flow from the separation area to the process area sides in relation to the rotation direction;
a center area that is located substantially in a center portion of the vacuum chamber in order to separate the first process area and the second process area, and has an ejection hole that ejects a second separation gas along the surface having the substrate receiving area;
an evacuation opening provided in the vacuum chamber in order to evacuate the vacuum chamber;
an upper holding member that may be pressed on an upper center portion of the turntable; and
a lower holding member that may be pressed on a lower center portion of the turntable in order to rotatably hold the turntable in cooperation with the upper holding member,
wherein an area where the upper holding member and the turntable contact each other is made of a ceramic material, and an area where the lower holding member and the turntable contact each other is made of a ceramic material.

16. A substrate process apparatus comprising:
a vacuum transport chamber inside of which a substrate transport unit is arranged;
a film deposition apparatus of claim 1, the film deposition apparatus being hermetically connected to the vacuum transport chamber; and
a preliminary vacuum chamber whose inside pressure may be switchable between an atmospheric pressure and a reduced pressure, the preliminary vacuum chamber being hermetically connected to the vacuum transport chamber.

17. A turntable rotatably provided in a film deposition apparatus and rotatably held in such a manner that an upper holding member is pressed on an upper center portion of the turntable and a lower holding member is pressed on a lower center portion of the turntable, the turntable comprising:
a ceramic film formed on areas of the turntable, the areas contacting the upper holding member and the lower holding member, respectively.

18. The turntable of claim 17, wherein the ceramic film has an upper mirror surface.

19. The turntable of claim 17, wherein the ceramic film is made of one of aluminum oxide, yttrium oxide, and a mixture of aluminum oxide and yttrium oxide.
